(19) United States
(12) Patent Application Publication
(10) Pub. No.: US 2026/0040489 A1
(43) Pub. Date: Feb. 5, 2026

(54) HEAT EXCHANGER, COOLING DEVICE, PROJECTOR, AND ELECTRONIC DEVICE

(71) Applicant: SEIKO EPSON CORPORATION, Tokyo (JP)

(72) Inventor: Shoichi NAGAMATSU, SHIOJIRI-SHI (JP)

(21) Appl. No.: 19/285,287

(22) Filed: Jul. 30, 2025

(30) Foreign Application Priority Data
Jul. 31, 2024 (JP) 2024-124457

(51) Int. Cl. H05K 7/20; G03B 21/16

(52) U.S. Cl. CPC H05K 7/20272; G03B 21/16

(57) ABSTRACT

A heat exchanger includes a housing having an accommodation chamber surrounded by first to fourth side surfaces; a first flow port disposed in the first side surface in a range from a half of a length to the third side surface from a center of the first side surface to the third side surface; a second flow port disposed in the first side surface in a range from a half of a length to the fourth side surface from a center of the first side surface to the fourth side surface; a third flow port disposed on the second side surface; the first to third main flow paths extending in the accommodation chamber; a plurality of first branch flow paths provided at a plurality of locations in the first main flow path; and a plurality of second branch flow paths provided at a plurality of locations in the second main flow path, and a plurality of third branch flow paths and fourth branch flow paths provided in the third main flow path, wherein a dimension ratio of a length of the accommodation chamber along the first side surface to a length of the accommodation chamber along the third side surface is 0.6 or more and 10.0 or less.

The present application is based on, and claims priority from JP Application Serial Number 2024-124457, filed Jul. 31, 2024, the disclosure of which is hereby incorporated by reference herein in its entirety.

### BACKGROUND

### 1. Technical Field

The present disclosure relates to a heat exchanger, a cooling device, a projector, and an electronic device.

### 2. Related Art

In the related art, a heat sink is known in which a flow path through which a cooling liquid flows is formed (for example, see JP-T-2020-522144).

The heat sink described in JP-T-2020-522144 has a plurality of fluid flow paths formed therein. The plurality of fluid flow paths are configured to enable a cooling fluid to flow from an inlet to an outlet of a slab, which is a plate shaped structure. The plurality of fluid flow paths includes at least two main flow paths and a plurality of bridging flow paths connecting the at least two main flow paths.

Each of the plurality of bridging paths has a locally increasing cross-section and a locally decreasing cross-section in the direction of flow of the cooling liquid, i.e. in the direction from one main flow path to the other main flow path. In such a bridging path, heat exchange occurs between the cooling liquid and the heat sink.

However, in the heat sink described in JP-T-2020-522144, although the contact area with the cooling liquid is increased and the efficiency of heat transfer to the cooling liquid is enhanced, there is a possibility that the heat sink is not sufficient as a cooling structure for a heat source having a high heat generation amount.

Therefore, there has been a demand for a heat exchanger having a configuration with further improved efficiency of heat transfer.

### SUMMARY

A heat exchanger according to a first aspect of the present disclosure includes a housing having a first side surface and a second side surface located on opposite sides, a third side surface and a fourth side surface that intersect both the first side surface and the second side surface, and that are located on opposite sides, and an accommodation chamber surrounded by the first side surface, the second side surface, the third side surface, and the fourth side surface; a first flow port disposed in the first side surface in a range from a half of a length to the third side surface from a center of the first side surface to the third side surface, and through which a refrigerant can flow; a second flow port disposed in the first side surface in a range from a half of a length to the fourth side surface from a center of the first side surface to the fourth side surface, and through which the refrigerant can flow; a third flow port that is disposed in the second side surface and through which the refrigerant can flow; a first main flow path that communicates with the outside of the housing via the first flow port and that extends in the accommodation chamber along a first target side surface that is one side surface of the first side surface and the third side surface; a second main flow path that communicates with the outside of the housing via the second flow port and that extends in the accommodation chamber along a second target side surface that is one side surface of the first side surface and the fourth side surface; a third main flow path that communicates with the outside of the housing via the third flow port and that extends in the accommodation chamber along one main flow path of the first main flow path and the second main flow path; a plurality of first branch flow paths that are provided at a plurality of locations in the first main flow path and that branch off from the first main flow path; a plurality of second branch flow paths that are provided at a plurality of locations in the second main flow path and that branch off from the second main flow path; a plurality of third branch flow paths provided in a portion of the third main flow path on the first main flow path side and communicating with at least one first branch flow path of the plurality of first branch flow paths; and a plurality of fourth branch flow paths provided in a portion of the third main flow path on the second main flow path side and communicating with at least one second branch flow path of the plurality of second branch flow paths, wherein a dimension ratio of a length of the accommodation chamber along the first side surface to a length of the accommodation chamber along the third side surface is 0.6 or more and 10.0 or less.

The cooling device according to a second aspect of the disclosure includes the heat exchanger according to the first aspect; a radiator that radiates heat received by the refrigerant in the heat exchanger; and a pump that circulates the refrigerant between the heat exchanger and the radiator.

A projector according to a third aspect of present disclosure includes the cooling device according to the second aspect; a light source; a light modulation element that modulates light emitted from the light source; a projection optical device that projects the modulated light; and a heat receiving plate provided on a heat-generating element of one of the light source and the light modulation element the heat exchanger of the cooling device is connected to the heat receiving plate in a heat transferable manner.

An electronic device according to a fourth aspect of the present disclosure includes the cooling device according to the second aspect; a heat-generating element having a heat receiving plate, wherein the heat exchanger of the cooling device is connected to the heat receiving plate in a heat transferable manner.

### BRIEF DESCRIPTION OF THE DRAWINGS

FIG. 1 is a schematic view showing a configuration of a projector according to a first embodiment.

FIG. 2 is a cross-sectional view showing an internal configuration of the heat exchanger according to the first embodiment.

FIG. 3 is a cross-sectional view showing an internal configuration of the heat exchanger according to the first embodiment.

FIG. 4 is a cross-sectional view showing an internal configuration of the heat exchanger according to the first embodiment.

FIG. 5 is a cross-sectional view showing an internal configuration of a heat exchanger according to a first comparative example.

FIG. 6 is a cross-sectional view showing an internal configuration of a heat exchanger according to a second comparative example.

FIG. 7 is a graph showing the efficiency of heat transfer to the refrigerant by the heat exchanger according to the first embodiment.

FIG. 8 is a cross-sectional view showing an internal configuration of a heat exchanger according to a third comparative example.

FIG. 9 is a cross-sectional view showing an internal configuration of the heat exchanger according to the first embodiment.

FIG. 10 is a cross-sectional view showing an internal configuration of the heat exchanger according to the first embodiment.

FIG. 11 is a cross-sectional view showing an internal configuration of the heat exchanger according to the first embodiment.

FIG. 12 is a cross-sectional view showing an internal configuration of the heat exchanger according to the first embodiment.

FIG. 13 is a cross-sectional view showing an internal configuration of the heat exchanger according to the first embodiment.

FIG. 14 is a cross-sectional view showing an internal configuration of the heat exchanger according to the first embodiment.

FIG. 15 is a cross-sectional view showing an internal configuration of the heat exchanger according to the first embodiment.

FIG. 16 is a cross-sectional view showing an internal configuration of the heat exchanger according to the first embodiment.

FIG. 17 is a graph showing the efficiency of heat transfer to the refrigerant by the heat exchanger according to the first embodiment.

FIG. 18 is a cross-sectional view showing the internal configuration of a heat exchanger included in a cooling device of a projector according to a second embodiment.

FIG. 19 is a graph showing the efficiency of heat transfer to the refrigerant by the heat exchanger according to the second embodiment.

FIG. 20 is a graph showing the efficiency of heat transfer to the refrigerant by the heat exchanger according to the second embodiment.

### DESCRIPTION OF EMBODIMENTS

### First Embodiment

Hereinafter, a first embodiment of the present disclosure will be described with reference to the drawings. Schematic configuration of projector

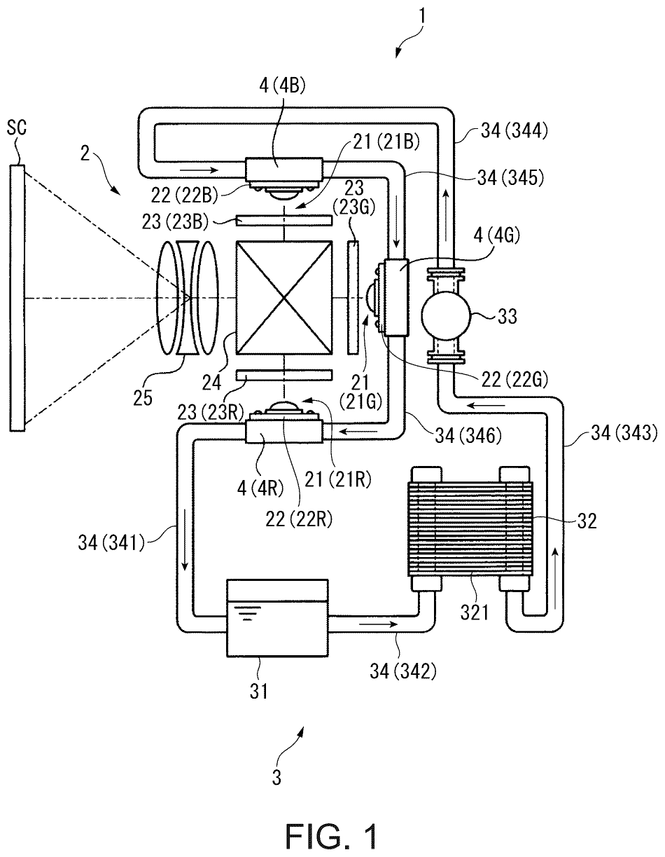

FIG. 1 is a schematic view showing configuration of a projector 1 according to a present embodiment.

The projector 1 according to the present embodiment is an example of an electronic device, and is an image display device that modulates light emitted from a light source to form image light corresponding to image information and that enlarges and projects the formed image light on a projection surface SC such as a screen. The projector 1 includes an image projection device 2 and a cooling device 3, as shown in FIG. 1. In addition, although not shown, the projector 1 includes a control device that controls the projector 1, a power supply device that supplies electric power to electronic components of the projector 1, and an exterior housing that accommodates the image projection device 2, the cooling device 3, the control device, and the power supply device.

### Configuration of Image Projection Device

The image projection device 2 generates the image light described above and projects the generated image light. The image projection device 2 includes three light sources 21, three heat receiving plates 22, three light modulation elements 23, a color combining element 24, and a projection optical device 25.

The three light sources 21 emit light that illuminates the three light modulation elements 23. The three light sources 21 include a red light source 21R, a green light source 21G, and a blue light source 21B. The red light source 21R emits red light to a red light modulation element 23R of the light modulation element 23. The green light source 21G emits green light to the green light modulation element 23G of the light modulation elements 23. The blue light source 21B emits blue light to a blue light modulation element 23B of the light modulation element 23. In the present embodiment, the red light source 21R, the green light source 21G, and the blue light source 21B are each configured with a light emitting element that emits light of a corresponding color. Examples of the light emitting element include a solid-state light source such as a light emitting diode (LED) and a laser diode (LD). Each of the three heat receiving plates 22 is disposed on the corresponding light source 21 among the three light sources 21. That is, the three heat receiving plates 22 include a heat receiving plate 22R that is heat-transferably connected to the red light source 21R, a heat receiving plate 22G that is heat-transferably connected to the green light source 21G, and a heat receiving plate 22B that is heat-transferably connected to the blue light source 21B. Each heat receiving plate 22 is connected to the heat exchanger 4 (to be described later) in a manner capable of heat transfer.

Each of the three light modulation elements 23 modulates incident light in accordance with image information input from the control device. The three light modulation elements 23 include a red light modulation element 23R, a green light modulation element 23G, and a blue light modulation element 23B. The red light modulation element 23R modulates the red light incident from the red light source 21R. The green light modulation element 23G modulates the green light incident from the green light source 21G. The blue light modulation element 23B modulates the blue light incident from the blue light source 21B. Each of the light modulation elements 23R, 23G, and 23B can be formed of a liquid-crystal light valve including a transmissive liquid-crystal panel, an incident-side polarizer provided on the light incident side of the transmissive liquid-crystal panel, and an exit-side polarizer provided on the light exit side of the transmissive liquid-crystal panel.

The color combining element 24 combines the red, green, and blue light incident from the light modulation elements 23R, 23G, and 23B with one another to form image light and outputs the image light formed to the projection optical device 25. In the present embodiment, the color combining element 24 is formed of a cross dichroic prism. However, the color combining element 24 is not limited to this, and can also be formed of a plurality of dichroic mirrors. The projection optical device 25 projects the image light incident from the color combining element 24 on the projection surface SC. The projection optical device 25 can be formed, for example, as a lens assembly including a plurality of lenses and a lens barrel that accommodates the plurality of lenses.

### Configuration of Cooling Device

The cooling device 3 cools the heat-generating element of the projector 1. The cooling device 3 includes the plurality of heat exchangers 4, a storage container 31, a radiator 32, a pump 33, and a plurality of pipes 34, and circulates a refrigerant to cool a heat-generating element connected to the heat exchanger 4. That is, the cooling device 3 may include a heat exchanger 4A, which is one type of the heat exchanger 4. The heat exchanger 4A will be described in detail later. Note that in the present embodiment, the refrigerant is a liquid refrigerant, but may be a gas refrigerant.

The plurality of pipes 34 connect the plurality of heat exchangers 4, the storage container 31, the radiator 32, and the pump 33 so that the refrigerant can flow therethrough, and constitute a circulation flow path of the refrigerant. The plurality of pipes 34 include a first pipe 341, a second pipe 342, a third pipe 343, a fourth pipe 344, a fifth pipe 345, and a sixth pipe 346. The first pipe 341 connects the red heat exchanger 4R, among the multiple heat exchangers 4, to the storage container 31. In the present embodiment, the first pipe 341 connects a third flow port 57 (to be described later) of the red heat exchanger 4R to the storage container 31. That is, the first pipe 341 allows the refrigerant discharged from the third flow port 57 of the red heat exchanger 4R to flow to the storage container 31. The second pipe 342 connects the storage container 31 and the radiator 32. The third pipe 343 connects the radiator 32 and the pump 33.

The fourth pipe 344 connects the pump 33 and the blue heat exchanger 4B of the plurality of heat exchangers 4. In the present embodiment, the fourth pipe 344 connects the pump 33 to a first flow port 55 and a second flow port 56 of the blue heat exchanger 4B. That is, the fourth pipe 344 divides the refrigerant sent out from the pump 33 into two parts, and causes one part of the refrigerant amongst the two parts of the refrigerant to flow to the first flow port 55 and the other part of the refrigerant to flow to the second flow port 56. The fifth pipe 345 connects the blue heat exchanger 4B and the green heat exchanger 4G among the plurality of heat exchangers 4. In the present embodiment, the fifth pipe 345 connects the third flow port 57 of the blue heat exchanger 4B, and the first flow port 55 and the second flow port 56 of the green heat exchanger 4G. That is, the fifth pipe 345 divides the refrigerant discharged from the third flow port 57 of the blue heat exchanger 4B into two parts, and causes one of the refrigerant among the two parts of the refrigerant to flow through the first flow port 55 of the green heat exchanger 4G and the other part of the refrigerant to flow through the second flow port 56 of the green heat exchanger 4G.

The sixth pipe 346 connects the green heat exchanger 4G and the red heat exchanger 4R. In the present embodiment, the sixth pipe 346 connects the third flow port 57 of the green heat exchanger 4G, and the first flow port 55 and the second flow port 56 of the red heat exchanger 4R. That is, the sixth pipe 346 divides the refrigerant discharged from the third flow port 57 of the green heat exchanger 4G into two parts, and causes one of the refrigerant among the two parts of the refrigerant to flow to the first flow port 55 of the red heat exchanger 4R and the other part of the refrigerant to flow to the second flow port 56 of the red heat exchanger 4R.

The storage container 31 is a tank that temporarily stores the refrigerant that has flowed through the plurality of heat exchangers 4. The radiator 32 cools the refrigerant flowing from the storage container 31. That is, the radiator 32 radiates the heat received by the refrigerant in the heat exchanger 4. The radiator 32 has a plurality of micro flow paths 321 in which the refrigerant flows, and cools the refrigerant by receiving heat from the refrigerant in each micro flow path. The refrigerant cooled by the radiator 32 flows to the pump 33 via the third pipe 343. Note that the radiator 32 radiates heat received from the refrigerant to the cooling gas flowing from a fan (not shown). The pump 33 circulates the refrigerant between the heat exchanger 4 and the radiator 32. The pump 33 sends the refrigerant flowing from the radiator 32 to the plurality of heat exchangers 4. In the present embodiment, the pump 33 feeds the refrigerant to the blue heat exchanger 4B via the fourth pipe 344.

### Configuration of Heat Exchanger

Each of the plurality of heat exchangers 4 is a so-called cold plate, and transfers heat received from a heat-generating element to a refrigerant flowing inside, thereby cooling the heat-generating element. In this embodiment, a plurality of heat exchangers 4 are heat-transferably connected to a heat receiving plate 22 disposed on a light source 21, which is one of the heat-generating elements. The plurality of heat exchangers 4 include the red heat exchanger 4R, the green heat exchanger 4G, and the blue heat exchanger 4B heat exchanger. The red heat exchanger 4R is connected to the heat receiving plate 22R in a heat transferable manner. The green heat exchanger 4G is connected to the heat receiving plate 22G in a heat transferable manner. The blue heat exchanger 4B is connected to the heat receiving plate 22B in a heat transferable manner.

### Configuration of Housing

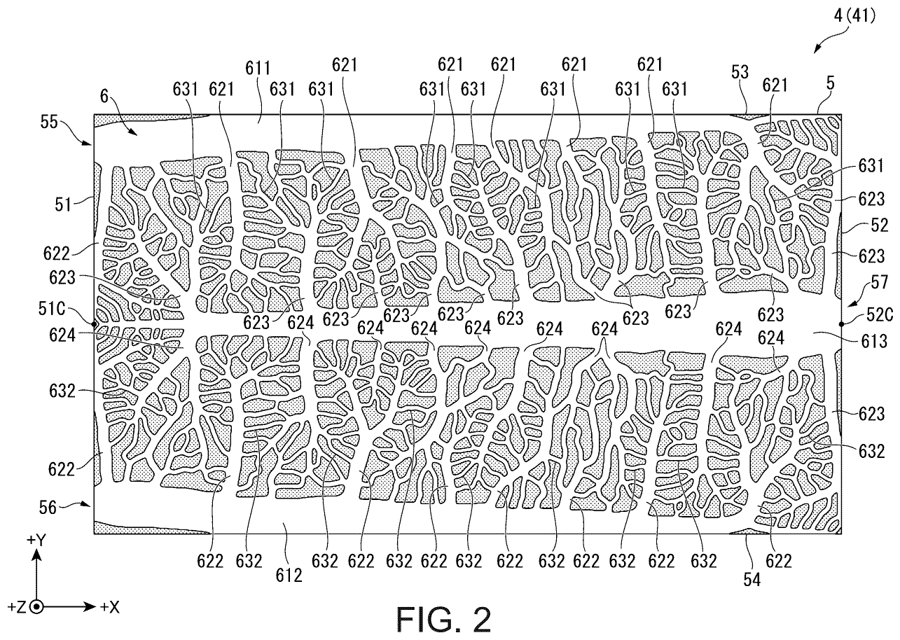

FIG. 2 is a cross-sectional view showing an internal configuration of the heat exchanger 4. Specifically, FIG. 2 is a cross-sectional view showing an internal configuration of the heat exchanger 41 of the heat exchanger 4, the heat exchanger 41 including the first flow port 55 provided at a position separated from the center 51C of the first side surface 51 toward the third side surface 53 by a length of 1, assuming that the length from the center 51C of the first side surface 51 to the third side surface 53 is 1, and the second flow port 56 provided at a position separated from the center 51C of the first side surface 51 toward the fourth side surface 54 by a length of 1, assuming that the length from the center 51C of the first side surface 51 to the fourth side surface 54 is 1. In FIG. 2, to facilitate understanding of the drawing, only some first branch flow paths 621 among the plurality of first branch flow paths 621 are denoted by reference numerals. The same applies to the second branch flow paths 622, the third branch flow paths 623, the fourth branch flow paths 624, the first narrow branch flow paths 631, and the second narrow branch flow paths 632. As shown in FIG. 2, each heat exchanger 4 includes a housing 5 formed in a substantially rectangular parallelepiped shape. The housing 5 is made of metal such as copper having high thermal conductivity. The housing 5 has a first side surface 51, a second side surface 52, a third side surface 53, and a fourth side surface 54, and also has a flat plate-shaped accommodation chamber 6 surrounded by the first side surface 51, the second side surface 52, the third side surface 53, and the fourth side surface 54.

Each of the first side surface 51, the second side surface 52, the third side surface 53, and the fourth side surface 54 is an outer surface of the housing 5. The first side surface 51 and the second side surface 52 are located on opposite sides to each other. The third side surface 53 and the fourth side surface 54 are located on opposite sides to each other. The third side surface 53 intersects each of the first side surface 51 and the second side surface 52. The fourth side surface 54 intersects each of the first side surface 51 and the second side surface 52.

The heat exchanger 4 further includes a first flow port 55, a second flow port 56, and a third flow port 57. The first flow port 55 is disposed in the first side surface 51. The first flow port 55 is a communication port that allows the outside of the housing 5 and the accommodation chamber 6 in the housing 5 to communicate with each other. The refrigerant can flow through the first flow port 55. The second flow port 56 is disposed on the first side surface 51. The second flow port 56 is a communication port that allows the outside of the housing 5 and the accommodation chamber 6 in the housing 5 to communicate with each other. The refrigerant can flow through the second flow port 56. The third flow port 57 is disposed at the center 52C of the second side surface 52. The third flow port 57 is a communication port that allows the outside of the housing 5 and the accommodation chamber 6 to communicate with each other. The refrigerant can flow through the third flow port 57.

In the following description, three directions orthogonal to each other are defined as a +X direction, a +Y direction, and a +Z direction. In the present embodiment, the +X direction is a direction from the first side surface 51 toward the second side surface 52, and the +Y direction is a direction from the fourth side surface 54 toward the third side surface 53. The +Z direction is a direction orthogonal to each of the +X direction and the +Y direction, and is, for example, a direction perpendicular to the paper surface on which FIG. 2 is shown.

Although not illustrated, a direction opposite to the +X direction is defined as a −X direction, a direction opposite to the +Y direction is defined as a −Y direction, and a direction opposite to the +Z direction is defined as a −Z direction. An axis along the +X direction is defined as an X axis, an axis along the +Y direction is defined as a Y axis, and an axis along the +Z direction is defined as a Z axis.

### Configuration of Accommodation Chamber

The accommodation chamber 6 is a portion that transfers heat transferred from the heat-generating element to the refrigerant flowing inside, and exchanges heat with the refrigerant when one of the first flow port 55 and the second flow port 56 and the third flow port 57 is used as an inlet port and the other is used as an outlet port. The shape of the accommodation chamber 6 is rectangular when viewed along the Z-axis.

The accommodation chamber 6 includes a plurality of main flow paths 611, 612, 613, a plurality of branch flow paths 621, 622, 623, 624, and a plurality of narrow branch flow paths 631, 632. The plurality of main flow paths 611, 612, 613, the plurality of branch flow paths 621, 622, 623, 624, and the plurality of narrow branch flow paths 631, 632 can be formed in the housing 5 by, for example, three dimensional molding. The accommodation chamber 6 including the main flow paths 611 to 613, the branch flow paths 621 to 624, and the narrow branch flow paths 631, 632 is configured to be line-symmetric with respect to an imaginary straight line that passes through the center 51C of the first side surface 51 and that is orthogonal to the first side surface 51. Specifically, the first main flow path 611 and the second main flow path 612 are disposed line-symmetrically with respect to the imaginary straight line, the first branch flow path 621 and the third branch flow path 623 are disposed line-symmetrically with respect to the imaginary straight line, the second branch flow path 622 and the fourth branch flow path 624 are disposed line-symmetrically with respect to the imaginary straight line, and the first narrow branch flow path 631 and the second narrow branch flow path 632 are disposed line-symmetrically with respect to the imaginary straight line.

### Configuration of Main Flow Paths

Each of the plurality of main flow paths 611, 612, 613 is a flow path that is connected to a corresponding flow port among the flow ports 55 to 57 and is configured to allow the refrigerant to flow therethrough. The first main flow path 611 is connected to the first flow port 55. The first main flow path 611 extends along a first target side surface, which is one of the first side surface 51 and the third side surface 53, in the accommodation chamber 6. When half of the length of the first side surface 51 is larger than the length of the third side surface 53, the first target side surface is the first side surface 51. When half of the length of the first side surface 51 is smaller than the length of the third side surface 53, the first target side surface is the third side surface 53. When half of the length of the first side surface 51 is equal to the length of the third side surface 53, the first target side surface is one of the first side surface 51 and the third side surface 53. In the heat exchanger 41, since the half of the length of the first side surface 51 is smaller than the length of the third side surface 53, the first main flow path 611 extends from the first side surface 51 toward the second side surface 52 in the accommodation chamber 6 along the third side surface 53, which is the first target side surface. Note that in the heat exchanger 41, the first main flow path 611 extends substantially linearly from the first flow port 55 toward the second side surface 52 along the third side surface 53. The flow path cross-sectional area of the first main flow path 611 becomes smaller as the first main flow path 611 extends toward the second side surface 52.

The second main flow path 612 is connected to the second flow port 56. The second main flow path 612 extends along a second target side surface, which is one of the first side surface 51 and the fourth side surface 54, in the accommodation chamber 6. When half of the length of the first side surface 51 is larger than the length of the fourth side surface 54, the second target side surface is the first side surface 51. When half of the length of the first side surface 51 is smaller than the length of the fourth side surface 54, the second target side surface is the fourth side surface 54. When half of the length of the first side surface 51 is equal to the length of the fourth side surface 54, the second target side surface is one of the first side surface 51 and the fourth side surface 54. In the heat exchanger 41, since the half of the length of the first side surface 51 is smaller than the length of the fourth side surface 54, the second main flow path 612 extends from the first side surface 51 toward the second side surface 52 in the accommodation chamber 6 along the fourth side surface 54, which is the second target side surface. Note that in the heat exchanger 41, the second main flow path 612 extends substantially linearly from the second flow port 56 toward the second side surface 52 along the fourth side surface 54. The flow path cross-sectional area of the second main flow path 612 becomes smaller as the second main flow path 612 extends toward the second side surface 52.

The third main flow path 613 is connected to the third flow port 57. The third main flow path 613 extends along the main flow path extending direction of one of the first main flow path 611 and the second main flow path 612 in the accommodation chamber 6. In the heat exchanger 41, the third main flow path 613 extends from the third flow port 57 along the extending direction of the first main flow path 611 extending along the third side surface 53 in the accommodation chamber 6. Specifically, the third main flow path 613 extends from the third flow port 57 toward the first side surface 51 through the center of the accommodation chamber 6 when viewed from the +Z direction. That is, the third main flow path 613 extends along the X axis in the accommodation chamber 6, between the first main flow path 611 and the second main flow path 612 with respect to the Y axis, from the third flow port 57, which is provided in the third side surface 53, toward the first side surface 51. Note that in the heat exchanger 41, the third main flow path 613 extends substantially linearly from the third flow port 57 toward the first side surface 51. The flow path cross-sectional area of the third main flow path 613 becomes smaller as the third main flow path 613 extends toward the first side surface 51.

### Configuration of Plurality of Branch Flow Paths

Each of the plurality of branch flow paths 621, 622, 623, and 624 is a flow path that is provided at a plurality of locations in a corresponding main flow path among the main flow paths 611, 612, and 613, and is the flow path that branches off and extends from the corresponding main flow path. The first branch flow paths 621 are provided at a plurality of locations of the first main flow path 611, and branch off and extend from the first main flow path 611. The flow path cross-sectional area of each of the plurality of first branch flow paths 621 is smaller than the flow path cross-sectional area of the first main flow path 611. Specifically, the flow path cross-sectional area of each first branch flow path 621 is smaller than the smallest flow path cross-sectional area in the first main flow path 611. Each of the first branch flow paths 621 extends in a curved shape. The second branch flow paths 622 are provided at a plurality of locations of the second main flow path 612, and branch off and extend from the second main flow path 612. The flow path cross-sectional area of each of the plurality of second branch flow paths 622 is smaller than the flow path cross-sectional area of the second main flow path 612. Specifically, the flow path cross-sectional area of each second branch flow path 622 is smaller than the smallest flow path cross-sectional area in the second main flow path 612. Each of the second branch flow paths 622 extends in a curved shape.

The third branch flow paths 623 are provided in a portion of the first main flow path 611 side of the third main flow path 613. That is, the plurality of third branch flow paths 623 are provided in a portion in the +Y direction, which is a portion on the first main flow path 611 side of the third main flow path 613. At least one third branch flow path 623 of the plurality of third branch flow paths 623 is in communication with at least one first branch flow path 621 of the plurality of first branch flow paths 621. Each of the third branch flow path 623 extends in a curved shape. The plurality of the fourth branch flow paths 624 is provided in a plurality in a portion of the second main flow path 612 side of the third main flow path 613. That is, the plurality of fourth branch flow paths 624 is provided in a portion that is in the −Y direction and that is a portion on the second main flow path 612 side of the third main flow path 613. At least one fourth branch flow path 624 of the plurality of fourth branch flow paths 624 is in communication with at least one second branch flow path 622 of the plurality of second branch flow path 622. Each of the fourth branch flow path 624 extends in a curved shape. The flow path cross-sectional area of each third branch flow path 623 is smaller than the flow path cross-sectional area of the third main flow path 613. Specifically, the flow path cross-sectional area of each third branch flow path 623 is smaller than the smallest flow path cross-sectional area in the third main flow path 613. Similarly, the flow path cross-sectional area of each fourth branch flow path 624 is smaller than the flow path cross-sectional area of the third main flow path 613. Specifically, the flow path cross-sectional area of each fourth branch flow path 624 is smaller than the smallest flow path cross-sectional area in the third main flow path 613.

### Configuration of Plurality of Narrow Branch Flow Paths

Each of the plurality of first narrow branch flow paths 631 is a mesh-like flow path that directly or indirectly communicates with the first main flow path 611 and the third main flow path 613, and the flow path cross-sectional area of each of the first narrow branch flow paths 631 is smaller than the flow path cross-sectional area of each of the first branch flow paths 621 and the flow path cross-sectional area of each of the third branch flow paths 623. The plurality of first narrow branch flow paths 631 may include a narrow branch flow path that connects the first main flow path 611 and the third main flow path 613 or the third branch flow path 623, or may include a branch flow path that connects the first branch flow path 621 and the third main flow path 613 or the third branch flow path 623. That is, the plurality of first narrow branch flow paths 631 may include a flow path that allows one first branch flow path 621 and one third branch flow path 623 to communicate with each other. One first narrow branch flow path 631 may be provided in one first branch flow path 621 or one third branch flow path 623, or a plurality of first narrow branch flow paths 631 may be provided in one first branch flow path 621 or one third branch flow path 623. Note that the first narrow branch flow path 631 extends in a curved shape.

Each of the plurality of second narrow branch flow paths 632 is a mesh-like flow path that directly or indirectly communicates with the second main flow path 612 and the third main flow path 613, and the flow path cross-sectional area of each second narrow branch flow path 632 is smaller than the flow path cross-sectional area of each of the second branch flow paths 622 and the flow path cross-sectional area of each of the fourth branch flow paths 624. The plurality of second narrow branch flow paths 632 may include a narrow branch flow path that brings the second main flow path 612 and the third main flow path 613 or the second main flow path 612 and the fourth branch flow path 624 into communication, or may include a branch flow path that brings the second branch flow path 622 and the third main flow path 613 or second branch flow path 622 and the fourth branch flow path 624 into communication. That is, the plurality of second narrow branch flow paths 632 may include a flow path that allows one second branch flow path 622 and one fourth branch flow path 624 to communicate with each other. A second narrow branch flow path 632 may be provided in one second branch flow path 622 or one fourth branch flow path 624, or plural second branch flow paths 632 may be provided in a single second branch flow path 622 or in a single fourth branch flow path 624. Note that the second narrow branch flow path 632 extends in a curved shape.

### Communication State of Each Flow Path

The first main flow path 611 and the third main flow path 613 do not directly communicate with each other. The first main flow path 611 communicates with the third main flow path 613 via at least one of the first branch flow path 621, the third branch flow path 623, and the first narrow branch flow path 631. The second main flow path 612 and the third main flow path 613 do not directly communicate with each other. The second main flow path 612 communicates with the third main flow path 613 via at least one of the second branch flow path 622, the fourth branch flow path 624, and the second narrow branch flow path 632.

### Other Examples of Arrangement Positions of First Flow Port and Second Flow Port

The position of the first flow port 55 communicating with the first main flow path 611 in the first side surface 51 and the position of the second flow port 56 communicating with the second main flow path 612 in the first side surface 51 can be made to be different depending on the heat exchanger 4. In other words, the distances between the center 51C of the first side surface 51 and the first flow port 55 and the distances between the center 51C and the second flow port 56 can be made different depending on the heat exchanger 4.

Heat Exchanger in which First Flow Port and Second Flow Port are Provided at Position of 0.75

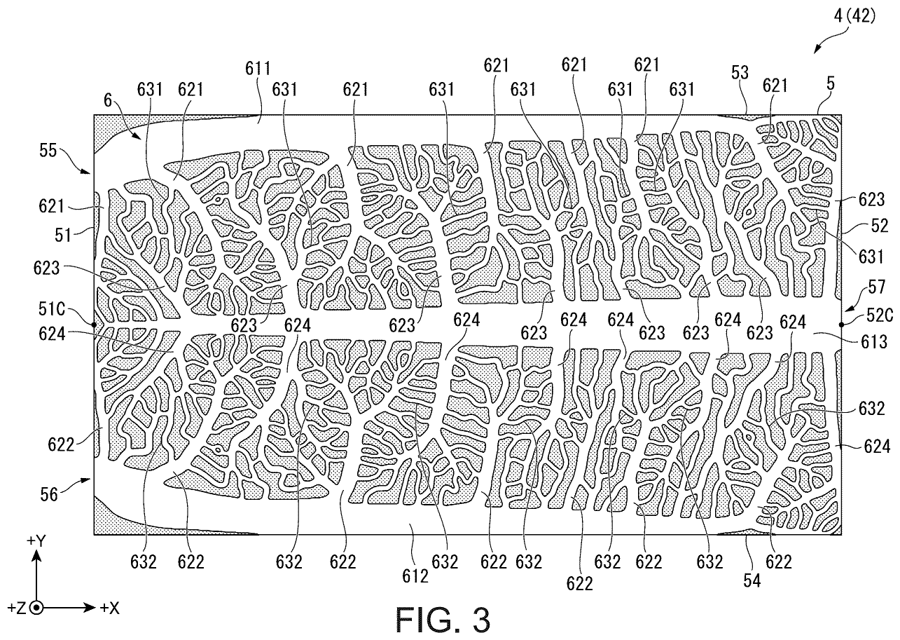

FIG. 3 is a cross-sectional view showing the internal configuration of the heat exchanger 42 in which the first flow port 55 is disposed at a position 0.75 from the center 51C portion in the +Y direction and the second flow port 56 is disposed at a position 0.75 from the center 51C portion in the −Y direction. In FIG. 3, only some first branch flow paths 621 of the plurality of first branch flow paths 621 are denoted by reference numerals. The same applies to the second branch flow paths 622, the third branch flow paths 623, the fourth branch flow paths 624, the first narrow branch flow paths 631, and the second narrow branch flow paths 632. For example, as shown in FIG. 3, the heat exchanger 42, which is one of the heat exchangers 4, has the same configuration and function as the heat exchanger 41 described above except that the positions of the first flow port 55 and the second flow port 56 in the first side surface 51 are different and the extending directions of the first main flow path 611 and the second main flow path 612 are different. In the heat exchanger 42, assuming that the length from the center 51C of the first side surface 51 to the third side surface 53 is 1, the first flow port 55 is disposed a length of 0.75 separated from the center 51C toward the third side surface 53. Similarly, in the heat exchanger 42, assuming that the length from the center 51C of the first side surface 51 to the fourth side surface 54 is 1, the second flow port 56 is disposed length of 0.75 separated from the center 51C toward the fourth side surface 54.

In the heat exchanger 42, the first main flow path 611 connected to the first flow port 55 extends from the first flow port 55 toward the third side surface 53 at an angle of approximately 75° with respect to the perpendicular line of the first side surface 51, and then extends along the third side surface 53 toward the second side surface 52 side. At this time, the flow path cross-sectional area of the first main flow path 611 decreases as the first main flow path 611 extends from the first flow port 55. Similarly, in the heat exchanger 42, the second main flow path 612 connected to the second flow port 56 extends from the second flow port 56 toward the fourth side surface 54 at an angle of approximately 75° with respect to the perpendicular line of the first side surface 51, and then extends along the fourth side surface 54 toward the second side surface 52 side. At this time, the flow path cross-sectional area of the second main flow path 612 decreases as the second main flow path 612 extends from the second flow port 56.

Heat Exchanger in which First Flow Port and Second Flow Port are Provided at Position of 0.5

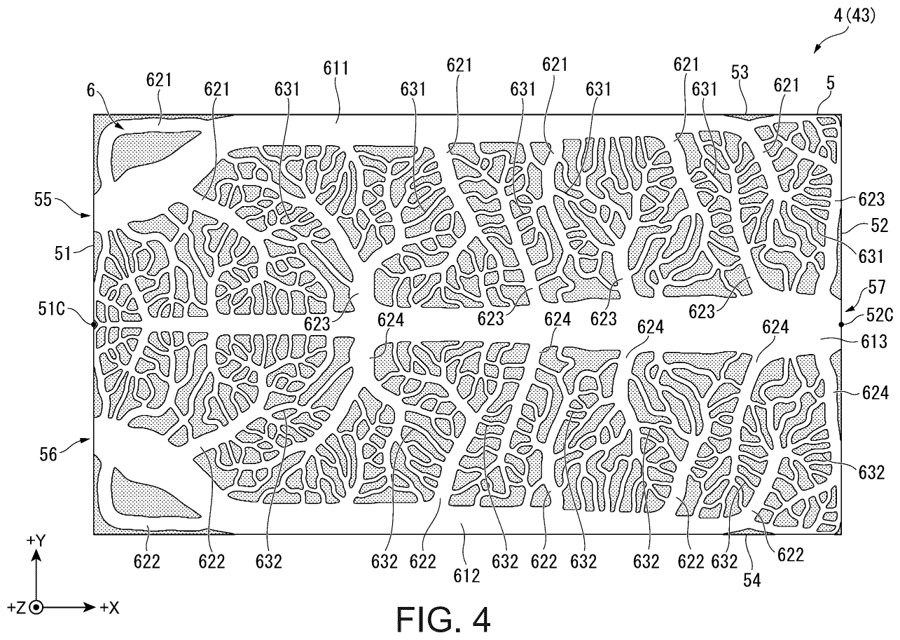

FIG. 4 is a cross-sectional view showing the internal configuration of the heat exchanger 43 in which the first flow port 55 is disposed at a position of 0.5 from the center 51C portion in the +Y direction and the second flow port 56 is disposed at a position of 0.5 from the center 51C portion in the −−Y direction. In FIG. 4, only some first branch flow paths 621 of the plurality of first branch flow paths 621 are denoted by reference numerals. The same applies to the second branch flow paths 622, the third branch flow paths 623, the fourth branch flow paths 624, the first narrow branch flow paths 631, and the second narrow branch flow paths 632. For example, as shown in FIG. 4, the heat exchanger 43, which is one of the heat exchangers 4, has the same configuration and function as the heat exchanger 41 described above except that the positions of the first flow port 55 and the second flow port 56 in the first side surface 51 are different and the extending directions of the first main flow path 611 and the second main flow path 612 are different. In the heat exchanger 43, assuming that the length from the center 51C of the first side surface 51 to the third side surface 53 is 1, the first flow port 55 is disposed at a length of 0.5 separated from the center 51C toward the third side surface 53. Similarly, in the heat exchanger 43, assuming that the length from the center 51C of the first side surface 51 to the fourth side surface 54 is 1, the second flow port 56 is disposed at a length of 0.5 separated from the center 51C toward the fourth side surface 54.

In the heat exchanger 43, the first main flow path 611 connected to the first flow port 55 extends from the first flow port 55 toward the third side surface 53 at an angle of approximately 60° with respect to the perpendicular line of the first side surface 51, and then extends along the third side surface 53 toward the second side surface 52 side. At this time, the flow path cross-sectional area of the first main flow path 611 decreases as the first main flow path 611 extends from the first flow port 55. Similarly, in the heat exchanger 43, the second main flow path 612 connected to the second flow port 56 extends from the second flow port 56 toward the fourth side surface 54 at an angle of approximately 60° with respect to the perpendicular line of the first side surface 51, and then extends along the fourth side surface 54 toward the second side surface 52 side. At this time, the flow path cross-sectional area of the second main flow path 612 decreases as the second main flow path 612 extends from the second flow port 56.

Note that in the heat exchanger 43, some first branch flow paths 621 of the plurality of first branch flow paths 621 are provided at the intersection of the first side surface 51 and the third side surface 53. Some of the first branch flow paths 621 branch off from the first main flow path 611 and communicate with the first main flow path 611 again. Similarly, some second branch flow paths 622 of the plurality of second branch flow paths 622 are provided at the intersection of the first side surface 51 and the fourth side surface 54. Some of the second branch flow paths 622 branch off from the second main flow path 612 and communicate with the second main flow path 612 again.

Heat Exchanger in which First Flow Port and Second Flow Port are Provided at Position of 0.25

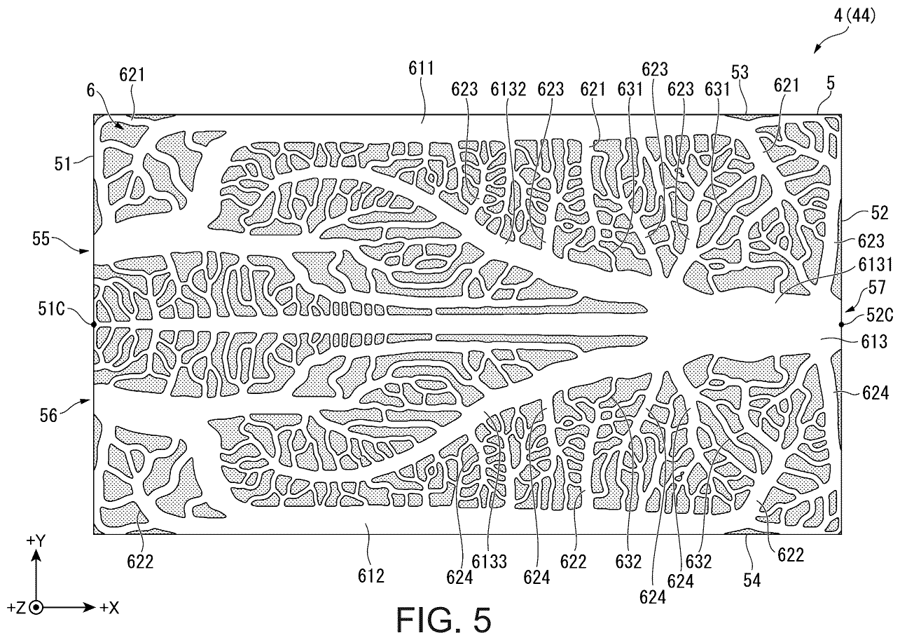

FIG. 5 is a cross-sectional view showing an internal configuration of a heat exchanger 44 according to first comparative example. To be specific, FIG. 5 is a cross-sectional view showing an internal configuration of the heat exchanger 44 in which the first flow port 55 is disposed at a position of 0.25 from the center 51C in the +Y direction and the second flow port 56 is disposed at a position of 0.25 from the center 51C portion in the −Y direction. In FIG. 5, only some first branch flow paths 621 of the plurality of first branch flow paths 621 are denoted by reference numerals. The same applies to the second branch flow paths 622, the third branch flow paths 623, the fourth branch flow paths 624, the first narrow branch flow paths 631, and the second narrow branch flow paths 632. As shown in FIG. 5, a heat exchanger 44 as a first comparative example with respect to the heat exchangers 41 to 43 has the same configuration and function as the heat exchanger 41 described above except that the positions of the first flow port 55 and the second flow port 56 in the first side surface 51 are different and the extending directions of the first main flow path 611 and the second main flow path 612 are different. In the heat exchanger 44, assuming that the length from the center 51C of the first side surface 51 to the third side surface 53 is 1, the first flow port 55 is disposed at a length of 0.25 separated from the center 51C toward the third side surface 53. Similarly, in the heat exchanger 44, assuming that the length from the center 51C of the first side surface 51 to the fourth side surface 54 is 1, the second flow port 56 is disposed at a length of 0.25 separated from the center 51C toward the fourth side surface 54.

In the heat exchanger 44, the first main flow path 611 connected to the first flow port 55 extends from the first flow port 55 toward the third side surface 53 along the perpendicular line of the first side surface 51, and further extends toward the third side surface 53 at an angle of approximately 90° to the perpendicular line to the first side surface 51, and then extends along the third side surface 53 toward the second side surface 52 side. At this time, the flow path cross-sectional area of the first main flow path 611 decreases as the first main flow path 611 extends from the first flow port 55. Similarly, in the heat exchanger 44, the second main flow path 612 connected to the second flow port 56 extends from the second flow port 56 toward the fourth side surface 54 along the perpendicular line of the first side surface 51, and further extends toward the fourth side surface 54 at an angle of approximately 90° to the perpendicular line to the first side surface 51, and then extends along the fourth side surface 54 toward the second side surface 52 side. At this time, the flow path cross-sectional area of the second main flow path 612 decreases as the second main flow path 612 extends from the second flow port 56.

Note that in the heat exchanger 44, some first branch flow paths 621 of the plurality of first branch flow paths 621 are provided at the intersection of the first side surface 51 and the third side surface 53. Some of the first branch flow paths 621 branch off from the first main flow path 611, and then further branch off, and communicate with the first main flow path 611 again. Similarly, some second branch flow paths 622 of the plurality of second branch flow paths 622 are provided at the intersection of the first side surface 51 and the fourth side surface 54. Some of the second branch flow paths 622 branch off from the second main flow path 612, and then further branch off, and communicate with the second main flow path 612 again.

The third main flow path 613 of the heat exchanger 44 includes a first partial flow path 6131, a second partial flow path 6132, and a third partial flow path 6133. The first partial flow path 6131 is connected to the third flow port 57 and extends from the third flow port 57 toward the first side surface 51. The first partial flow path 6131 communicates with the outside of the accommodation chamber 6 via the third flow port 57. The second partial flow path 6132 extends from the first partial flow path 6131 toward the first side surface 51 side and toward the third side surface 53 side. The third partial flow path 6133 extends from the first partial flow path 6131 toward the first side surface 51 side and toward the fourth side surface 54 side. In the heat exchanger 44, the third branch flow paths 623 are provided in the first partial flow path 6131 and the second partial flow path 6132, and the fourth branch flow paths 624 are provided in the first partial flow path 6131 and the third partial flow path 6133.

Heat Exchanger in which First Flow Port and Second Flow Port are Provided at Position 0

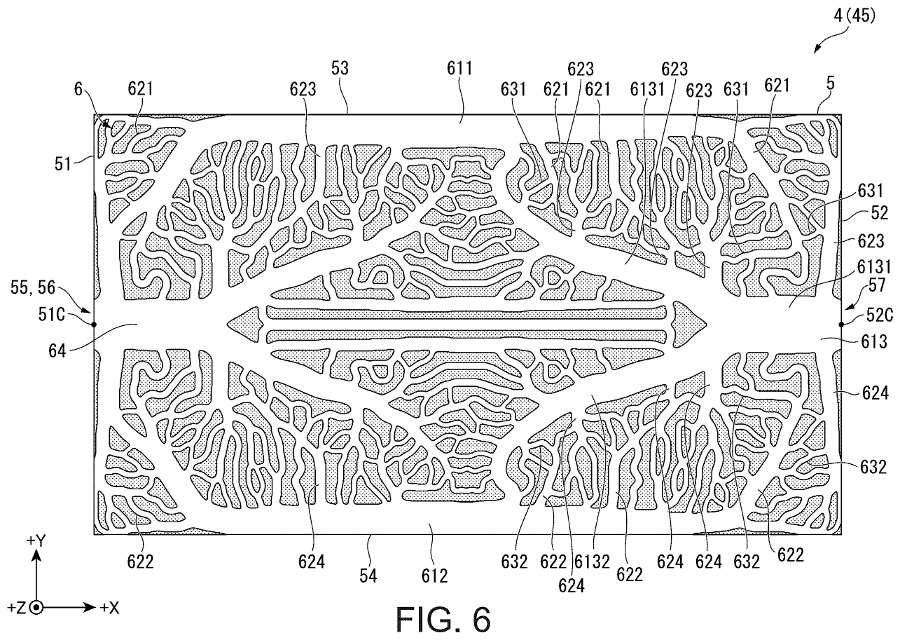

FIG. 6 is a cross-sectional view showing an internal configuration of a heat exchanger 45 according to a second comparative example. To be specific, FIG. 6 is a cross-sectional view showing an internal configuration of the heat exchanger 45 in which the first flow port 55 is disposed at a position of 0 from the center 51C portion in the +Y direction and the second flow port 56 is disposed at a position of 0 from the center 51C portion in the −Y direction. That is, FIG. 6 is a cross-sectional view showing the internal configuration of the heat exchanger 45 in which the first flow port 55 and the second flow port 56 are disposed in the center 51C. In FIG. 6, only some first branch flow paths 621 of the plurality of first branch flow paths 621 are denoted by reference numerals. The same applies to the second branch flow paths 622, the third branch flow paths 623, the fourth branch flow paths 624, the first narrow branch flow paths 631, and the second narrow branch flow paths 632. As shown in FIG. 6, the heat exchanger 45 as a second comparative example with respect to the heat exchangers 41 to 43 has the same configuration and function as those of the heat exchanger 41 described above except that the positions of the first flow port 55 and the second flow port 56 in the first side surface 51 are different and the extending directions of the first main flow path 611 and the second main flow path 612 are different. In the heat exchanger 45, assuming that the length from the center 51C of the first side surface 51 to the third side surface 53 is 1, the first flow port 55 is disposed at a length of 0 separated from the center 51C toward the third side surface 53. Similarly, assuming that the length from the center 51C of the first side surface 51 to the fourth side surface 54 is 1, the second flow port 56 is disposed at a length of 0 separated from the center 51C toward the fourth side surface 54. That is, in the heat exchanger 45, the first flow port 55 and the second flow port 56 are disposed at the center 51C of the first side surface 51 so as to be shifted from each other in the Z-axis.

In the heat exchanger 45, the first main flow path 611 connected to the first flow port 55 extends from the first flow port 55 toward the third side surface 53 at an angle of approximately 90° with respect to the perpendicular line of the first side surface 51, and further extends toward the third side surface 53 at an angle of approximately 45° with respect to the perpendicular line of the first side surface 51, and then extends along the third side surface 53 toward the second side surface 52 side. At this time, the flow path cross-sectional area of the first main flow path 611 decreases as the first main flow path 611 extends from the first flow port 55. Similarly, in the heat exchanger 45, the second main flow path 612 connected to the second flow port 56 extends from the second flow port 56 toward the fourth side surface 54 at an angle of approximately 90° with respect to the perpendicular line of the first side surface 51, and further extends toward the fourth side surface 54 at an angle of approximately 45° with respect to the perpendicular line of the first side surface 51, and then extends along the fourth side surface 54 toward the second side surface 52 side. At this time, the flow path cross-sectional area of the second main flow path 612 decreases as the second main flow path 612 extends from the second flow port 56.

In addition, the accommodation chamber 6 of the heat exchanger 45 is provided with a merge flow path 64 that extends from the first flow port 55 and the second flow port 56 toward the second side surface 52, and that branches off from and merges with the first main flow path 611 and the second main flow path 612. The flow path cross-sectional area of the merge flow path 64 is larger than the flow path cross-sectional area of the first main flow path 611 and the second main flow path 612. The merge flow path 64 is provided with a part of the plurality of first branch flow paths 621, a part of the plurality of second branch flow paths 622, a part of the plurality of first narrow branch flow paths 631, and a part of the plurality of second narrow branch flow paths 632.

Note that in the heat exchanger 45, some first branch flow paths 621 of the plurality of first branch flow paths 621 are provided at the intersection of the first side surface 51 and the third side surface 53. Some of the first branch flow paths 621 branch off from the first main flow path 611, and then further branch off, and communicate with the first main flow path 611 again. Similarly, in the heat exchanger 45, some second branch flow paths 622 of the plurality of second branch flow paths 622 are provided at the intersection of the first side surface 51 and the fourth side surface 54. Some of the second branch flow paths 622 branch off from the second main flow path 612, and then further branch off, and communicate with the second main flow path 612 again. The third main flow path 613 of the heat exchanger 45 is similar to the third main flow path 613 of the heat exchanger 44.

### Efficiency of Heat Transfer of Heat Exchanger According to Positions of First Flow Port and Second Flow Port

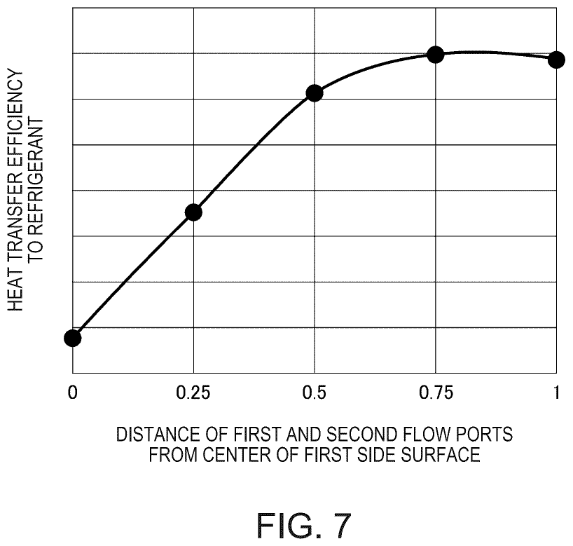

FIG. 7 is a graph showing the efficiency of heat transfer to the refrigerant by the heat exchangers 41 to 45, which have the first flow port 55 and the second flow port 56 at different positions. The efficiency of heat transfer to the refrigerant by the heat exchanger 4 varies depending on the positions of the first flow port 55 and the second flow port 56 in the first side surface 51. The inventor of the present disclosure has investigated the efficiency of heat transfer to the refrigerant in each of the heat exchangers 41 to 45 described above. As a result, as shown in FIG. 7, it was found that the heat exchangers 41 to 43, in which the first flow port 55 and the second flow port 56 are disposed at positions separated from the center 51C of the first side surface 51 by a length of 0.5 or more and 1 or less, have relatively high efficiency of heat transfer to the refrigerant, and the heat exchangers 44 and 45, in which the first flow port 55 and the second flow port 56 are disposed at positions separated from the center 51C of the first side surface 51 by a length of 0 or more and less than 0.5, have relatively low efficiency of heat transfer to the refrigerant. It was found that, among the heat exchangers 41 to 43, the efficiency of heat transfer to the refrigerant of the heat exchangers 41 and 42, in which the flow ports 55 and 56 are disposed at a position separated by a length of 0.75 or more and 1 or less from the center 51C of the first side surface 51, is higher than the efficiency of heat transfer to the refrigerant of the heat exchanger 43, in which the flow ports 55 and 56 are disposed at a position separated by a length of 0.5 from the center 51C of the first side surface 51. Furthermore, it was found that among the efficiency of heat transfer to the heat exchangers 41 to 45, the efficiency of heat transfer to the refrigerant of the heat exchanger 42, in which the flow ports 55, 56 are located at a position separated by the length of 0.75 from the center 51C of the first side surface 51, has the highest efficiency of heat transfer to the refrigerant.

For this reason, it is desirable to employ, for the cooling device 3, any of the heat exchangers 41 to 43 having a first flow port 55 that is positioned separated from the center 51C of the first side surface 51 toward the third side surface 53 by a length of 0.5 or more and 1 or less, assuming that the length from the center 51C of the first side surface 51 to the third side surface 53 is 1, and a second flow port 56 that is positioned separated from the center 51C of the first side surface 51 toward the fourth side surface 54 by a length of 0.5 or more and 1 or less, assuming that the length from the center 51C of the first side surface 51 to the fourth side surface 54 is 1. Further, it is desirable to employ, for the cooling device 3, either of the heat exchangers 41, 42 having the first flow port 55 that is positioned separated from the center 51C of the first side surface 51 toward the third side surface 53 by a length of 0.75 or more and 1 or less and the second flow port 56 positioned separated from the center 51C of the first side surface 51 toward the fourth side surface 54 by a length of 0.75 or more and 1 or less.

### Dimension Ratio of Dimension Along the First Side Surface and Dimension Along the Third Side Surface

The inventor of the present disclosure further examined the relationship between the dimension ratio L1/L2 of the length L2 of the accommodation chamber 6 along the first side surface 51 to the length L1 of the accommodation chamber 6 along the third side surface 53, and the efficiency of heat transfer to the refrigerant by the heat exchanger 4. Hereinafter, since the accommodation chamber 6 is formed in a rectangular shape when viewed along the Z-axis, the dimension ratio L2/L1 may be abbreviated as an aspect ratio.

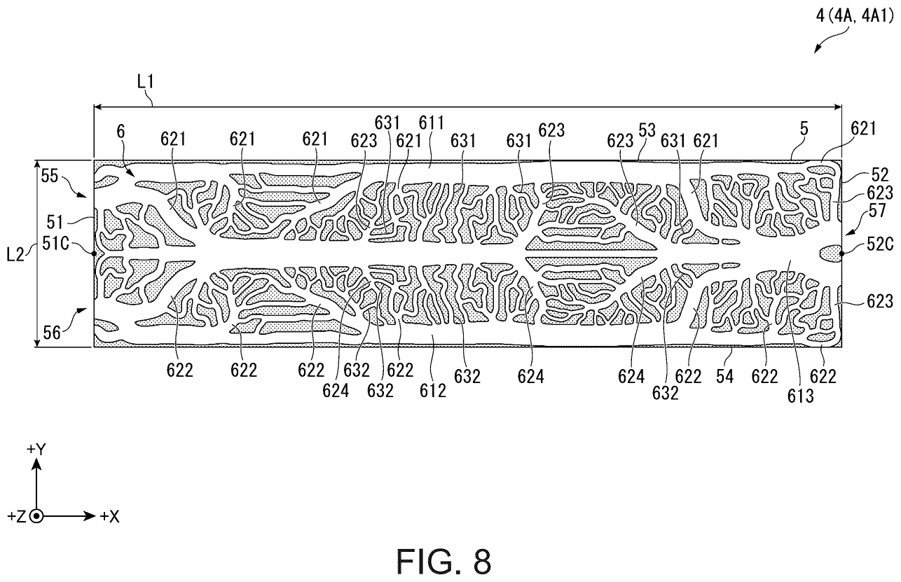

FIGS. 8 to 16 are cross-sectional views showing internal configurations of heat exchanger 4A having different aspect ratios. That is, FIGS. 8 to 16 are diagrams showing cross sections of the heat exchanger 4A having different aspect ratios along the XY plane. Note that FIG. 8 is a cross-sectional view showing an internal configuration of a heat exchanger 4A1 according to a third comparative example. The XY plane is a plane defined by the +X directions intersecting the first side surface 51 and the +Y directions intersecting the third side surface 53. The heat exchanger 4A is one type of the heat exchanger 4, constitutes the cooling device 3, and can be connected to the heat receiving plate 22 in a heat transferable manner. The heat exchanger 4A is a cold plate that can be adopted in the cooling device 3, and transfers heat received from the heat-generating element to the refrigerant flowing inside to cool the heat-generating element. As shown in FIGS. 8 to 16, the heat exchanger 4A includes a housing 5 having a rectangular accommodation chamber 6 surrounded by a first side surface 51, a second side surface 52, a third side surface 53, and a fourth side surface 54. Similarly to the heat exchanger 42, the heat exchanger 4A is a heat exchanger 4 in which the first flow port 55 is disposed at a position separated from the center 51C of the first side surface 51 toward the third side surface 53 by a length of 0.75, assuming that the length from the center 51C to the third side surface 53 is 1, and the second flow port 56 is disposed at a position separated from the center 51C toward the fourth side surface 54 by a length of 0.75, assuming that the length from the center 51C of the first side surface 51 to the fourth side surface 54 is 1.

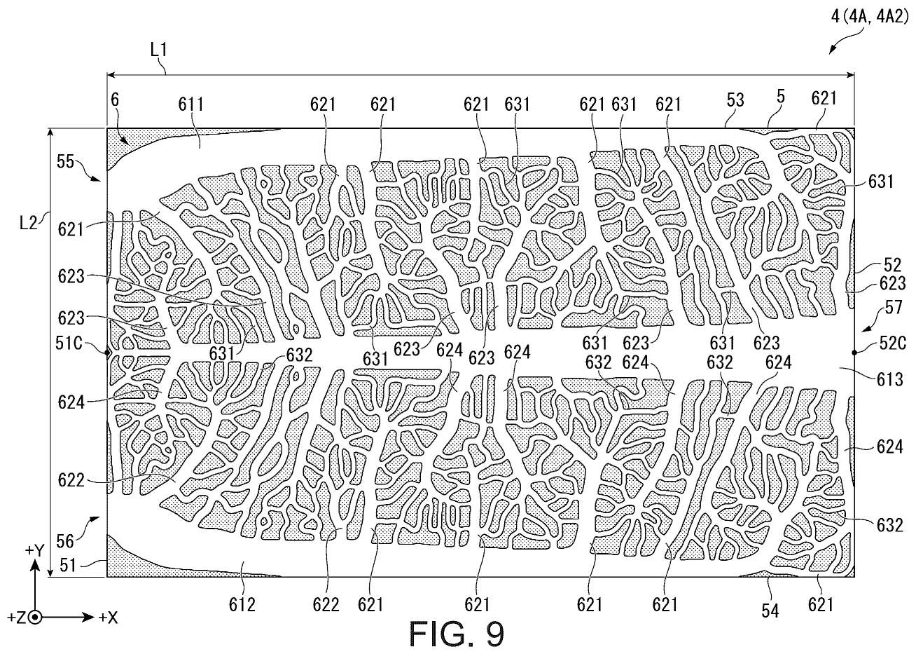

The heat exchanger 4A includes heat exchangers 4A1, 4A2, 4A3, 4A4, 4A5, 4A6, 4A7, 4A8, and 4A9, whose aspect ratios are in the range of 0.25 or more and 15.0 or less. The aspect ratio of the heat exchanger 4A1 shown in FIG. 8 is 0.25. The heat exchanger 4A1 is a heat exchanger that is a third comparative example with respect to the heat exchangers 4A2 to 4A9 shown in FIGS. 9 to 16. The aspect ratio of the heat exchanger 4A2 shown in FIG. 9 is 0.60.

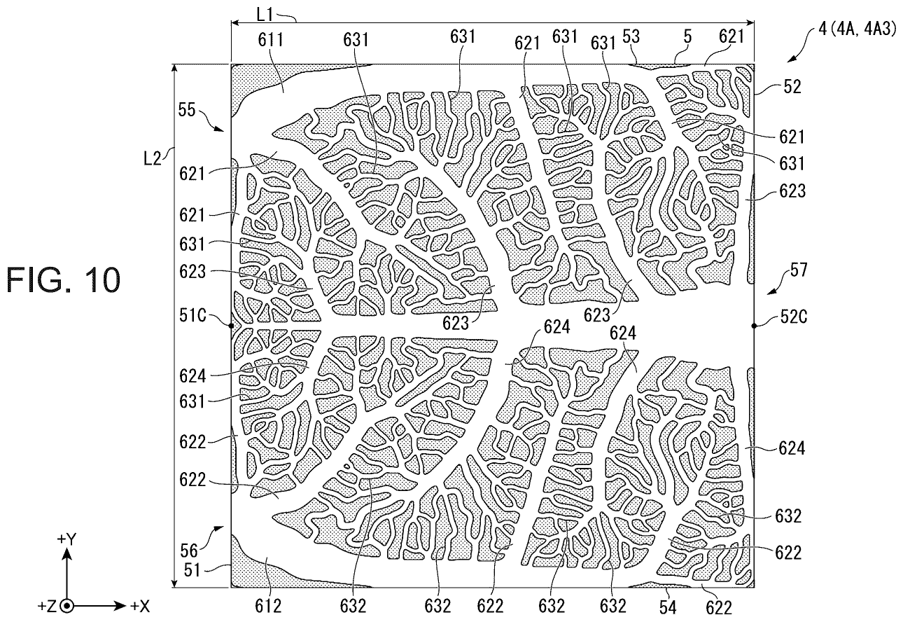

The aspect ratio of the heat exchanger 4A3 shown in FIG. 10 is 1.00.

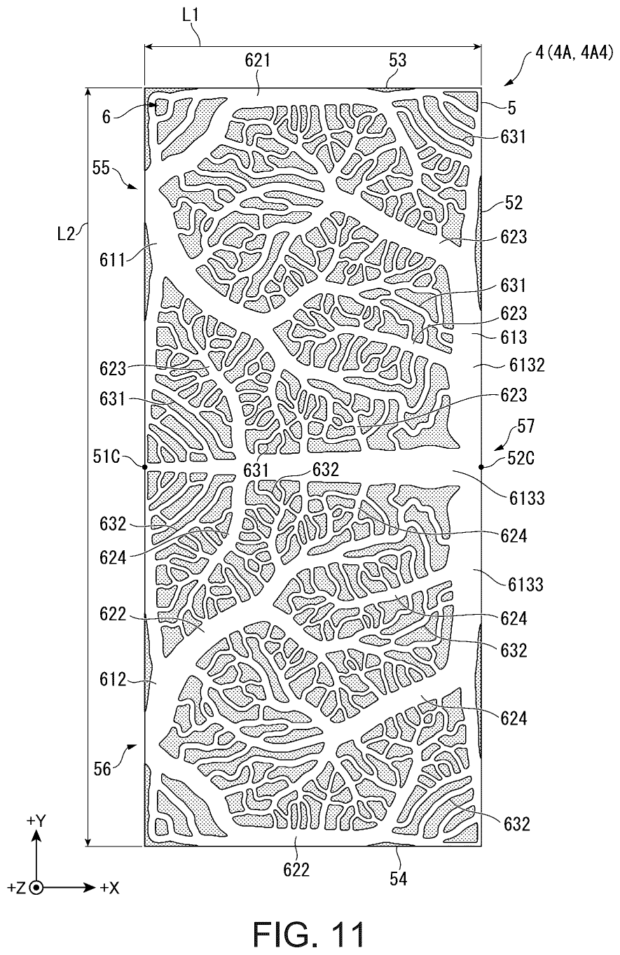

The aspect ratio of the heat exchanger 4A4 shown in FIG. 11 is 2.24.

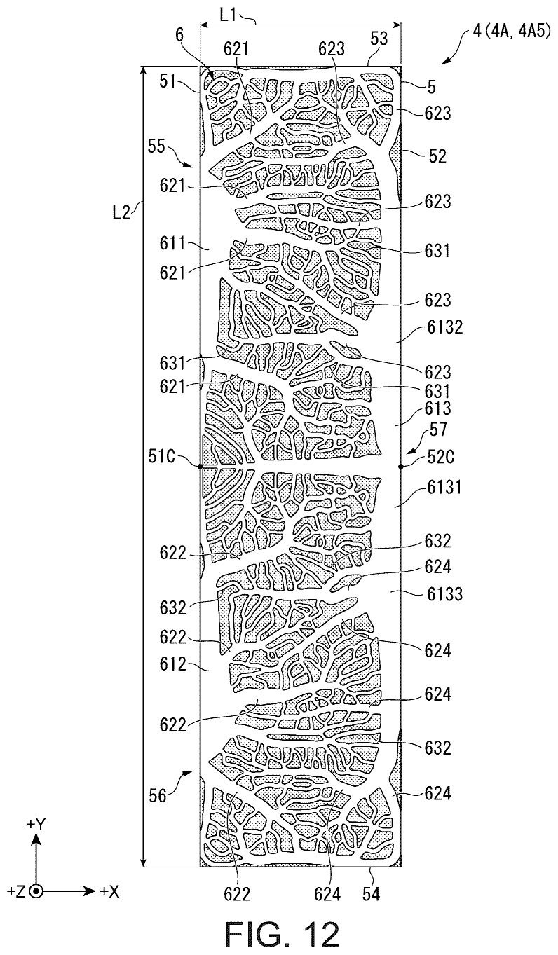

The aspect ratio of the heat exchanger 4A5 shown in FIG. 12 is 4.00.

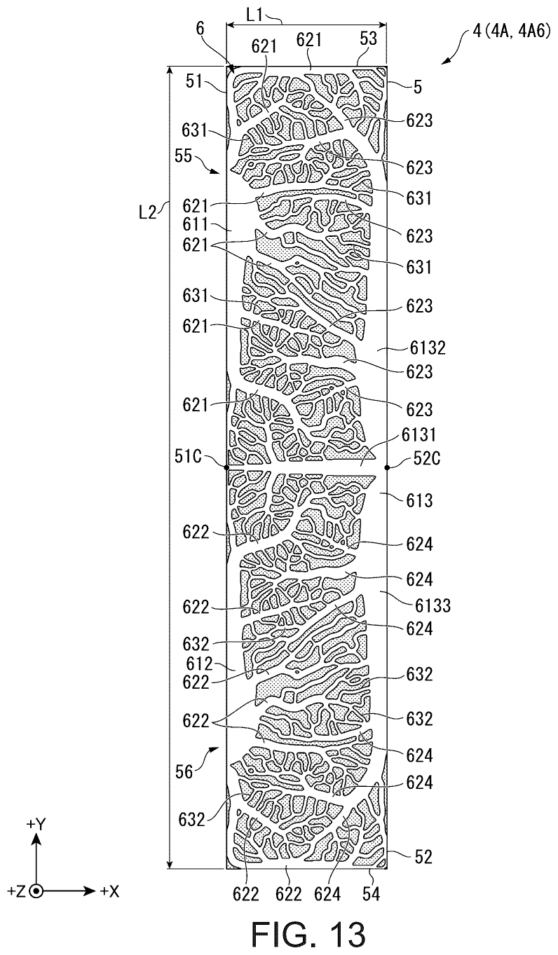

The aspect ratio of the heat exchanger 4A6 shown in FIG. 13 is 5.00.

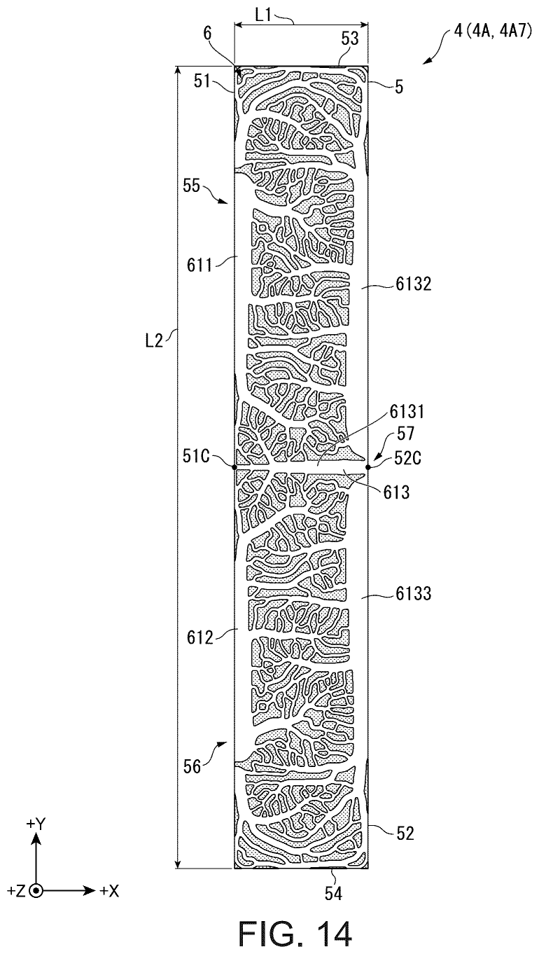

The aspect ratio of the heat exchanger 4A7 shown in FIG. 14 is 6.00.

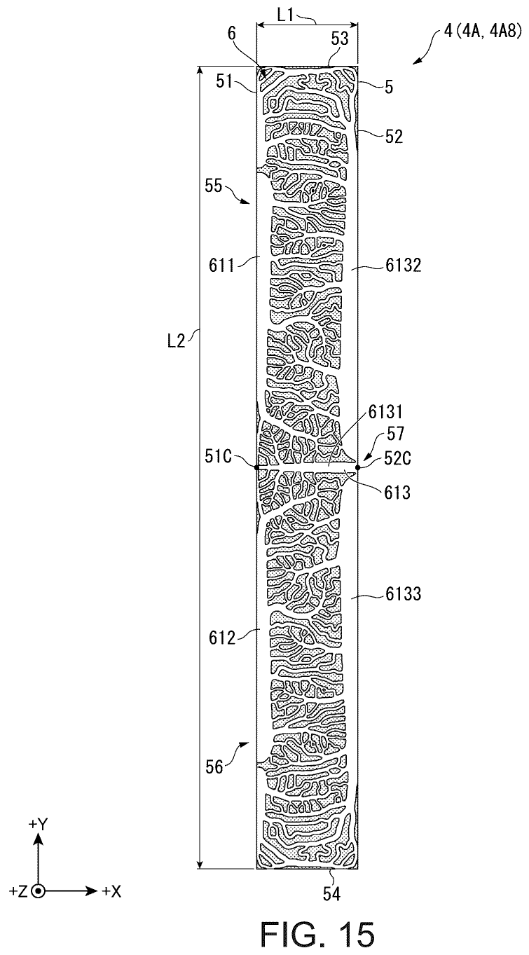

The aspect ratio of the heat exchanger 4A8 shown in FIG. 15 is 8.00.

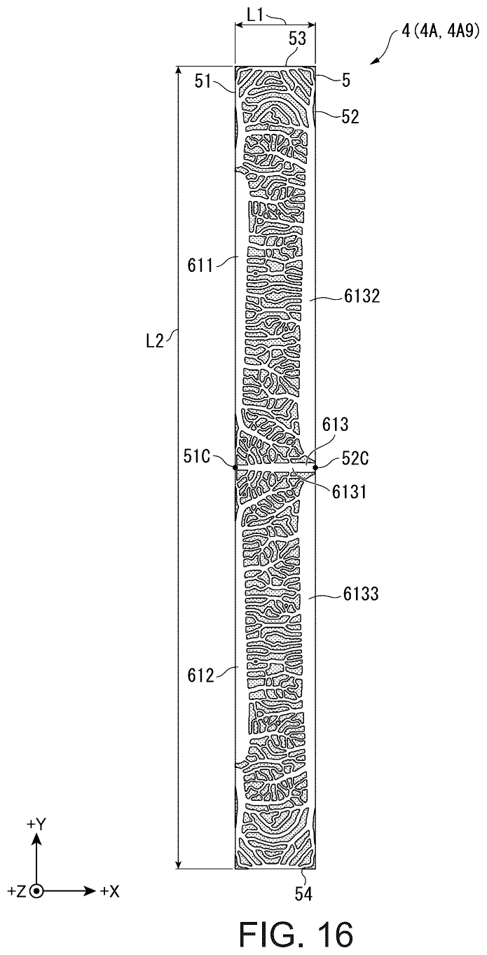

The aspect ratio of the heat exchanger 4A9 shown in FIG. 16 is 10.00.

Although not shown, a heat exchanger 4A having an aspect ratio of 15.0 is referred to as a heat exchanger 4A10.

The accommodation chamber 6 of the heat exchanger 4A includes a first main flow path 611, a second main flow path 612, and a third main flow path 613. Although reference numerals are omitted in the heat exchangers 4A7 to 4A9 shown in FIGS. 14 to 16, the accommodation chamber 6 includes a first branch flow path 621, a second branch flow path 622, a third branch flow path 623, a fourth branch flow path 624, a first narrow branch flow path 631, and a second narrow branch flow path 632.

Note that in the heat exchangers 4A1 to 4A3, the dimension L2/2, which is half the dimension L2 of the accommodation chamber 6 along the first side surface 51, is smaller than the dimension L1 of the accommodation chamber 6 along the third side surface 53. Therefore, the first main flow path 611 extends along the third side surface 53 as the first target side surface. In the heat exchangers 4A1 to 4A3, the dimension L2/2, which is half the dimension L2 of the accommodation chamber 6 along the first side surface 51, is smaller than the dimension of the accommodation chamber 6 along the fourth side surface 54. Therefore, the second main flow path 612 extends along the fourth side surface 54 as the second target side surface. On the other hand, in the heat exchangers 4A4 to 4A10, the dimension L2/2, which is half the dimension L2 of the accommodation chamber 6 along the first side surface 51, is larger than the dimension L1 of the accommodation chamber 6 along the third side surface 53. Therefore, the first main flow path 611 extends along the first side surface 51 as the first target side surface. In the heat exchangers 4A4 to 4A10, the dimension L2/2, which is half of the dimension L2 of the accommodation chamber 6 along the first side surface 51, is larger than the dimension of the accommodation chamber 6 along the fourth side surface 54. Therefore, the second main flow path 612 extends along the first side surface 51 as the second target side surface. Note that although not shown, when the dimension f the dimension L2 of the accommodation chamber 6 along the first side surface 51, is equal to the dimension L1 of the accommodation chamber 6 along the third side surface 53, the first main flow path 611 extends along the first target side surface, which is at least one of the first side surface 51 and the third side surface 53. When the dimension L2/2, which is half the dimension L2 of the accommodation chamber 6 along the first side surface 51, is equal to the dimension of the accommodation chamber 6 along the fourth side surface 54, the second main flow path 612 extends along the second target side surface, which is at least one of the first side surface 51 and the fourth side surface 54.

In the heat exchangers 4A1 to 4A3, the third main flow path 613 extends along one of the first main flow path 611 and the second main flow path 612. Specifically, in the heat exchangers 4A1 to 4A3, the third main flow path 613 extends from the third flow port 57 toward the first side surface 51 in a direction orthogonal to the second side surface 52, and the flow path cross-sectional area of the third main flow path 613 become smaller toward the first side surface 51. In the heat exchangers 4A4 to 4A10, the third main flow path 613 has a first partial flow path 6131, a second partial flow path 6132, and a third partial flow path 6133. The first partial flow path 6131 extends from the third flow port 57 toward the first side surface 51. The second partial flow path 6132 extends from the first partial flow path 6131 toward the third side surface 53 along the second side surface 52, and the third partial flow path 6133 extends from the first partial flow path 6131 toward the fourth side surface 54 along the second side surface 52. The flow path cross-sectional area of each partial flow path 6131, 6132, and 6133 decreases as the distance from the third flow port 57 increases. For example, the flow path cross-sectional area of the first partial flow path 6131 becomes smaller toward the extending direction from the third flow port 57.

### Efficiency of Heat Transfer of Heat Exchanger According to Aspect Ratio

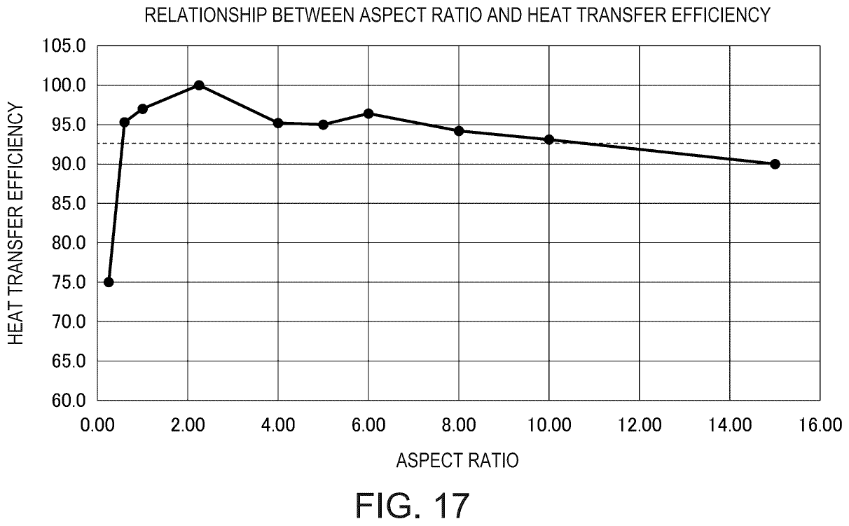

FIG. 17 is a graph showing efficiency of heat transfer to the refrigerant by the heat exchangers 4A1 to 4A10 having different aspect ratios, that is, the dimension ratio L2/L1. Note that the graph shown in FIG. 17 shows efficiency of heat transfer of each of the other heat exchangers 4A1 to 4A3 and 4A5 to 4A10 expressed as a percentage, when the efficiency of heat transfer of heat exchanger 4A4, which has the highest efficiency of heat transfer and has an aspect ratio of 2.25, is set to 100%. The inventor of the present disclosure investigated the efficiency of heat transfer of the heat exchangers 4A1 to 4A10 described above in order to examine the relationship between the aspect ratio and the efficiencies of heat transfer of the heat exchangers. Note that in the investigation, the amount of refrigerant supplied per unit time to each heat exchanger 4A was set to be the same.

As a result of the investigation, it was found that, as shown in FIG. 17, the efficiency of heat transfer of the heat exchangers 4A2 to 4A9, which have an aspect ratio of 0.6 or more and 10.0 or less, is relatively high, while the efficiency of heat transfer of the heat exchanger 4A1, which has an aspect ratio of less than 0.6, and the efficiency of heat transfer of the heat exchanger 4A10, which has an aspect ratio of more than 10.0, are relatively low. That is, the efficiencies of heat transfer of the heat exchangers 4A2 to 4A9 were higher than the efficiency of heat transfer of the heat exchanger 4A1 and the efficiency of heat transfer of the heat exchanger 4A10 of a third comparative example. In other words, assuming that the highest efficiency of heat transfer among the efficiency of heat transfer of the heat exchangers 4A1 to 4A10 is 100%, and that a good efficiency of heat transfer is 93%, then the heat exchangers 4A that have a efficiency of heat transfer of 93% or more are the heat exchangers 4A2 to 4A9, which have an aspect ratio of 0.6 or more and 10.0 or less. Therefore, it was found that the efficiency of heat transfer of each of the heat exchangers 4A2 to 4A9 having an aspect ratio of 0.6 or more and 10.0 or less was good. Therefore, it is desirable that the cooling device 3 employs any one of the heat exchangers 4A2 to 4A9.

The reason why the efficiency of heat transfer of each of the heat exchangers 4A1 to 4A9 is so good is considered to be as follows. In the heat exchanger 4A1 having an aspect ratio of less than 0.6 and the heat exchanger 4A10 having an aspect ratio of more than 10.0, the dimensions of each of the main flow paths 611, 612, 613 in the extension direction thereof are large. For example, in heat exchangers 4A1 to 4A3, the first main flow path 611 extends along the third side surface 53, and the dimension of the first main flow path 611 along the third side surface 53 in heat exchanger 4A1 is larger than the dimension of the first main flow path 611 along the third side surface 53 in heat exchangers 4A2 and 4A3. For example, in heat exchangers 4A4 to 4A10, the first main flow path 611 extends along the first side surface 51, and the dimension of the first main flow path 611 along the first side surface 51 in heat exchanger 4A10 is larger than the dimension of the first main flow path 611 along the first side surface 51 in heat exchangers 4A4 to 4A9. The same applies to the second main flow path 612 and the third main flow path 613.

When the refrigerant t flowing in the accommodation chamber 6 flows from the first flow port 55 and the second flow port 56 to the third flow port 57, if the pressure of the refrigerant supplied to the first main flow path 611 and the second main flow path 612 is small, the refrigerant stagnates in a portion on the downstream side in the flow direction of the refrigerant in each main flow paths 611, 612, and it is difficult to cause the refrigerant to flow through the entire accommodation chamber 6. On the other hand, when the pressure of the refrigerant supplied to the first main flow path 611 and the second main flow path 612 is large, it becomes difficult for the refrigerant to flow from the portion on the upstream side of each main flow path 611, 612 in the flow direction of the refrigerant to the first branch flow path 621, and it is difficult to cause the refrigerant to flow in the entire accommodation chamber 6. The same applies to the case where the refrigerant flowing through the accommodation chamber 6 flows from the third flow port 57 to the first flow port 55 and the second flow port 56. For these reasons, it is believed that the efficiency of heat transfer of the heat exchanger 4A1 having an aspect ratio of less than 0.6 is low.

In contrast, in the heat exchangers 4A2 to 4A9 in which the aspect ratio is 0.6 or more and 10.0 or less, the dimensions of the main flow paths 611, 612, and 613 in the extending direction thereof can be made smaller than in the heat exchanger 4A1 having an aspect ratio of less than 0.6. This makes it possible to facilitate the flow of the refrigerant through the entire accommodation chamber 6 in the heat exchangers 4A2 to 4A9. Therefore, in the heat exchangers 4A2 to 4A9 having the aspect ratio of 0.6 or more and 10.0 or less, the efficiency of heat transfer of the heat transferred to the heat exchangers 4A2 to 4A9 to the refrigerant can be increased.

Note that assuming that the efficiency of heat transfer of heat exchanger 4A4 having an aspect ratio of 2.25 is 100%, the efficiency of heat transfer of heat exchangers 4A3, 4A4, and 4A5 having aspect ratios of 1.0 or more and 4.0 or less is 95% or more. Therefore, it is desirable to employ in the cooling device 3 any one of the heat exchangers 4A3, 4A4, and 4A5, which have a higher efficiency of heat transfer than efficiency of heat transfer of the heat exchangers 4A2 and 4A6 to 4A9.

In the heat exchangers 4A1 to 4A10, assuming that the length from the center 51C of the first side surface 51 to the third side surface 53 is 1, the first flow port 55 is disposed at a position separated from the center 51C of the first side surface 51 toward the third side surface 53 by a length of 0.75 and, assuming that the length from the center 51C of the first side surface 51 to the fourth side surface 54 is 1, the second flow port 56 is disposed at a position separated from the center 51C of the first side surface 51 toward the fourth side surface 54 by a length of 0.75. However, assuming that the length from the center 51C of the first side surface 51 to the third side surface 53 is 1, the first flow port 55 may be disposed at a position separated from the center 51C toward the third side surface 53 by a length of 0.5 or more and 1.0 or less and, assuming that the length from the center 51C of the first side surface 51 to the fourth side surface 54 is 1, the second flow port 56 may be disposed at a position separated from the center 51C toward the fourth side surface 54 by a length of 0.5 or more and 1.0 or less. In the heat exchanger in which the flow ports 55, 56 are disposed at such a position, the relationship between the aspect ratio and the efficiency of heat transfer is established in the same manner as described above. Therefore, the aspect ratio of the heat exchangers in which the first flow port 55 is disposed in the range from the half of the length from the center 51C of the first side surface 51 to the third side surface 53 to the third side surface 53 and the second flow port 56 is disposed in the range from the half of the length from the center 51C of the first side surface 51 to the fourth side surface 54 to the fourth side surface 54 is desirably 0.6 or more and 10.0 or less. Further, the aspect ratio of the heat exchanger is more desirably 1.0 or more and 4.0 or less.

### Effects of First Embodiment

The projector 1 according to the present embodiment described above has the following effects. The projector 1 corresponds to an electronic device, and includes a cooling device 3 and a light source 21, which is a heat-generating element having a heat receiving plate 22. Specifically, the projector 1 includes a light source 21, a heat receiving plate 22, a light modulation element 23, a projection optical device 25, and a cooling device 3. The heat receiving plate 22 is provided in the light source 21, which is one of the heat-generating elements amongst the light source 21 and the light modulation element 23. The heat receiving plate 22 is connected to the heat exchanger 4A of the cooling device 3 in a heat transferable manner. The light modulation element 23 modulates the light emitted from the light source 21. The projection optical device 25 projects the light modulated by the light modulation element 23. The cooling device 3 includes a heat exchanger 4A, a radiator 32, and a pump 33. The radiator 32 radiates heat that the refrigerant receives in the heat exchanger 4A. The pump 33 circulates the refrigerant between the heat exchanger 4A and the radiator 32.

The heat exchanger 4A includes a housing 5, a first main flow path 611, a second main flow path 612, a third main flow path 613, a first branch flow path 621, a second branch flow path 622, a third branch flow path 623, a fourth branch flow path 624, a first flow port 55, a second flow port 56, and a third flow port 57. The housing 5 includes a first side surface 51, a second side surface 52, a third side surface 53, a fourth side surface 54, and an accommodation chamber 6. The first side surface 51 and the second side surface 52 are located on opposite sides to each other. The third side surface 53 and the fourth side surface 54 intersect both the first side surface 51 and the second side surface 52, and are located on opposite sides to each other. The accommodation chamber 6 is surrounded by the first side surface 51, the second side surface 52, the third side surface 53, and the fourth side surface 54.

The first flow port 55 is disposed in the first side surface 51 in a range from a half of a length from the center 51C of the first side surface 51 to the third side surface 53, to the third side surface 53. That is, assuming that the length from the center 51C of the first side surface 51 to the third side surface 53 is 1, the first flow port 55 is disposed at a position within a range of 0.5 or more and 1 or less from the center 51C of the first side surface 51 toward the third side surface 53. The refrigerant can flow through the first flow port 55. The second flow port 56 is disposed in the first side surface 51 in a range from a half of a length from the center 51C of the first side surface 51 to the fourth side surface 54, to the fourth side surface 54. That is, assuming that the length from the center 51C of the first side surface 51 to the fourth side surface 54 is 1, the second flow port 56 is disposed at a position within a range of 0.5 or more and 1 or less from the center 51C of the first side surface 51 toward the fourth side surface 54. The refrigerant can flow through the second flow port 56. The third flow port 57 is disposed on the second side surface. The refrigerant can flow through the third flow port 57.

The first main flow path 611 communicates with the outside of the housing 5 via the first flow port 55. The first main flow path 611 extends in the accommodation chamber 6 along a first target side surface, which is one side surface amongst the first side surface 51 and the third side surface 53. The second main flow path 612 communicates with the outside of the housing 5 via the second flow port 56. The second main flow path 612 extends in the accommodation chamber 6 along a second target side surface, which is one side surface amongst the first side surface 51 and the fourth side surface 54. The third main flow path 613 communicates with the outside of the housing 5 via the third flow port 57. The third main flow path 613 extends in the accommodation chamber 6 along one main flow path amongst the first main flow path 611 and the second main flow path 612.

The first branch flow paths 621 are provided at a plurality of locations in the first main flow path 611. Each of the plurality of first branch flow paths 621 branches off from the first main flow path 611. The second branch flow paths 622 are provided at a plurality of locations of the second main flow path 612. Each of the plurality of second branch flow paths 622 branches off from the second main flow path 612. The third branch flow paths 623 are provided in a portion of the first main flow path 611 side of the third main flow path 613. At least one third branch flow path 623 of the plurality of third branch flow paths 623 is in communication with at least one first branch flow path 621 of the plurality of first branch flow paths 621. The plurality of the fourth branch flow paths 624 is provided in a plurality in a portion of the second main flow path 612 side of the third main flow path 613. At least one fourth branch flow path 624 of the plurality of fourth branch flow paths 624 is in communication with at least one second branch flow path 622 of the plurality of second branch flow paths 622. In the heat exchangers 4A2 to 4A9 among the heat exchangers 4A, assuming that the length of the accommodation chamber 6 along the third side surface 53 is a length L1 and the length of the accommodation chamber 6 along the first side surface 51 is a length L2, the dimension ratio L2/L1 of the heat exchangers 4A2 to 4A9 is 0.6 or more and 10.0 or less.

According to such a configuration, the first flow port 55 is disposed at a position in a range from a half of the length from the center 51C of the first side surface 51 to the third side surface 53 to the third side surface 53 in the first side surface 51, and the second flow port 56 is disposed at a position in a range from a half of the length from the center 51C of the first side surface 51 to the fourth side surface 54 to the fourth side surface 54 in the first side surface 51. According to this configuration, as shown by the results of testing by the inventor of present disclosure, the efficiency of heat transfer to the refrigerant by the heat exchanger 4A can be increased. In the heat exchangers 4A2 to 4A9 among the heat exchangers 4A, the dimension ratio L2/L1 of the length L2 of the accommodation chamber 6 along the first side surface 51 to the length L1 of the accommodation chamber 6 along the third side surface 53 is 0.6 or more and 10.0 or less. This makes it possible to increase the efficiency of heat transfer to the refrigerant, compared to when the dimension ratio L2/L1 is less than 0.6 and exceeds 10.0. Therefore, the heat exchangers 4A2 to 4A9 can be configured to have high efficiency of heat transfer to the refrigerant. The cooling device 3 including the heat exchangers 4A2 to 4A9 can be configured as a cooling device with high cooling efficiency for a heat-generating element. This increases the cooling efficiency of the light source 21, so that even if the amount of light incident on the light modulation element 23 from the light source 21 is increased, the temperature rise of the light source 21 can be suppressed, thereby making it possible to configure a projector 1 capable of projecting high-brightness image light. That is, since the cooling efficiency of the heat-generating element can be enhanced, an electronic device capable of operating stably can be configured.

In the heat exchangers 4A3, 4A4, and 4A5 among the heat exchangers 4A, the dimension ratio L2/L1 of the length L2 of the first side surface 51 to the length L1 along the third side surface 53 of the accommodation chamber 6 is 1.0 or more and 4.0 or less. According to such a configuration, the refrigerant can be easily circulated efficiently in the entire accommodation chamber 6, and the pressure loss of the refrigerant can be further reduced. Therefore, the efficiency of heat transfer to the refrigerant by the heat exchangers 4A3, 4A4, and 4A5 can be further enhanced.

In the heat exchangers 4A2 to 4A9, the accommodation chamber 6 is formed in a rectangular shape when viewed from the +Z direction, which is orthogonal to each of the +X direction orthogonal to the first side surface 51 and the +Y direction orthogonal to the third side surface 53. Note that the +X direction corresponds to a first direction, the +Y direction corresponds to a second direction, and the +Z direction corresponds to a third direction. According to such a configuration, it is possible to easily circulate the refrigerant from one flow port to the other flow port among the first flow port 55 and the second flow port 56, and the third flow port 57 while spreading the refrigerant over the entire accommodation chamber 6. Therefore, the efficiency of heat transfer to the refrigerant by the heat exchangers 4A2 to 4A9 can be further enhanced.

In the heat exchangers 4A2 to 4A9, the accommodation chambers 6 are configured to be line-symmetric with respect to the imaginary straight line that passes through the center 51C of the first side surface 51 and that is orthogonal to the first side surface 51. According to such a configuration, the design of the accommodation chamber 6 in which the flow paths 611 to 613, 621 to 624, 631, and 632 are provided, and further the design of the heat exchangers 4A2 to 4A9, can be simplified.

In the heat exchangers 4A2 to 4A9, the flow path cross-sectional area of the first branch flow path 621 is smaller than the flow path cross-sectional area of the first main flow path 611. The flow path cross-sectional area of the second branch flow path 622 is smaller than the flow path cross-sectional area of the second main flow path 612. Each of the flow path cross-sectional area of the third branch flow path 623 and the flow path cross-sectional area of the fourth branch flow path 624 is smaller than the flow path cross-sectional area of the third main flow path 613. According to such a configuration, a larger number of the first branch flow paths 621 can be provided in the first main flow path 611, and a larger number of the second branch flow paths 622 can be provided in the second main flow path 612. Similarly, a larger number of the third branch flow paths 623 may be provided in the third main flow path 613, and a larger number of the fourth branch flow paths 624 may be provided in the third main flow path 613. Therefore, the contact area with the refrigerant in the accommodation chamber 6 can be increased, and thus the efficiency of heat transfer to the refrigerant by the heat exchangers 4A2 to 4A9 can be increased.

The heat exchangers 4A2 to 4A9 include a plurality of the first narrow branch flow paths 631 and a plurality of the second narrow branch flow paths 632. The flow path cross-sectional area of each of the plurality of first narrow branch flow paths 631 is smaller than the flow path cross-sectional area of the first branch flow path 621 and the flow path cross-sectional area of the third branch flow path 623. The plurality of first narrow branch flow paths 631 include a flow path that allows the first branch flow path 621 and the third branch flow path 623 to communicate with each other. The flow path cross-sectional area of each of the plurality of second narrow branch flow paths 632 is smaller than the flow path cross-sectional area of the second branch flow path 622 and the flow path cross-sectional area of the fourth branch flow path 624. The plurality of second narrow branch flow paths 632 include a flow path that allows the second branch flow path 622 and the fourth branch flow path 624 to communicate with each other. According to such a configuration, the surface area of the flow path can be increased over the entire accommodation chamber 6, and thus, the contact area with the refrigerant in the accommodation chamber 6 can be enlarged, and an increase in pressure loss can be suppressed. This makes it possible to increase the efficiency of heat transfer to the refrigerant by the heat exchangers 4A2 to 4A9.

In the heat exchangers 4A2 to 4A9, the first target side surface along which the first main flow path 611 extends is the first side surface 51 when half of the length of the first side surface 51 is larger than the length of the third side surface 53, is the third side surface 53 when half of the length of the first side surface 51 is smaller than the length of the third side surface 53, and is at least one of the first side surface 51 and the third side surface 53 when half of the length of the first side surface 51 is equal to the length of the third side surface 53. The second target side surface along which the second main flow path 612 extends is the first side surface 51 when half of the length of the first side surface 51 is larger than the length of the fourth side surface 54, is the fourth side surface 54 when half of the length of the first side surface 51 is smaller than the length of the fourth side surface 54, and is at least one of the first side surface 51 and the fourth side surface 54 when half of the length of the first side surface 51 is equal to the length of the fourth side surface 54. According to such a configuration, the first main flow path 611 can be extended linearly and elongated in the accommodation chamber 6, and the second main flow path 612 can be extended linearly and elongated in the accommodation chamber 6. Accordingly, since the flow path resistance of the first main flow path 611 and the flow path resistance of the second main flow path 612 can be reduced, it is possible to suppress an increase in the pressure loss of the refrigerant. Therefore, the efficiency of heat transfer to the refrigerant by the heat exchangers 4A2 to 4A9 can be enhanced.

In the heat exchangers 4A2 to 4A9, assuming that the length from the center 51C of the first side surface 51 to the third side surface 53 is 1, the first flow port 55 may be disposed at a position separated from the center 51C of the first side surface 51 toward the third side surface 53 by a length of 0.75 or more and 1 or less. In the heat exchangers 4A2 to 4A9, assuming that the length from the center 51C of the first side surface 51 to the fourth side surface 54 is 1, the second flow port 56 may be disposed at a position separated from the center 51C of the first side surface 51 toward the fourth side surface 54 by a length of 0.75 or more and 1 or less. According to such a configuration, each of the first main flow path 611 and the second main flow path 612 can be extended substantially linearly. This reduces the flow resistance of each main flow paths 611, 612 and further increases the contact area with the refrigerant in the accommodation chamber 6. Even when the first flow port 55 and the second flow port 56 are disposed at the above-described positions, the aspect ratio of the accommodation chamber 6 is 0.6 or more and 10.0 or less, and thus the refrigerant can be easily efficiently circulated in the entire accommodation chamber 6, and the pressure loss of the refrigerant can be further reduced. Therefore, the efficiency of heat transfer to the refrigerant by the heat exchangers 4A2 to 4A9 can be further enhanced.

### Second Embodiment

Next, a second embodiment of the present disclosure will be described. The projector according to the present embodiment has the same configuration as that of the projector 1 according to the first embodiment, but the configuration of the heat exchanger configured to the cooling device 3 is different. Specifically, the heat exchanger according to the present embodiment further includes a fourth flow port and a fourth main flow path. Note that in the following description, the same or substantially the same parts as those described above are denoted by the same reference numerals, and the description thereof will be omitted.

### Schematic Configuration of Projector

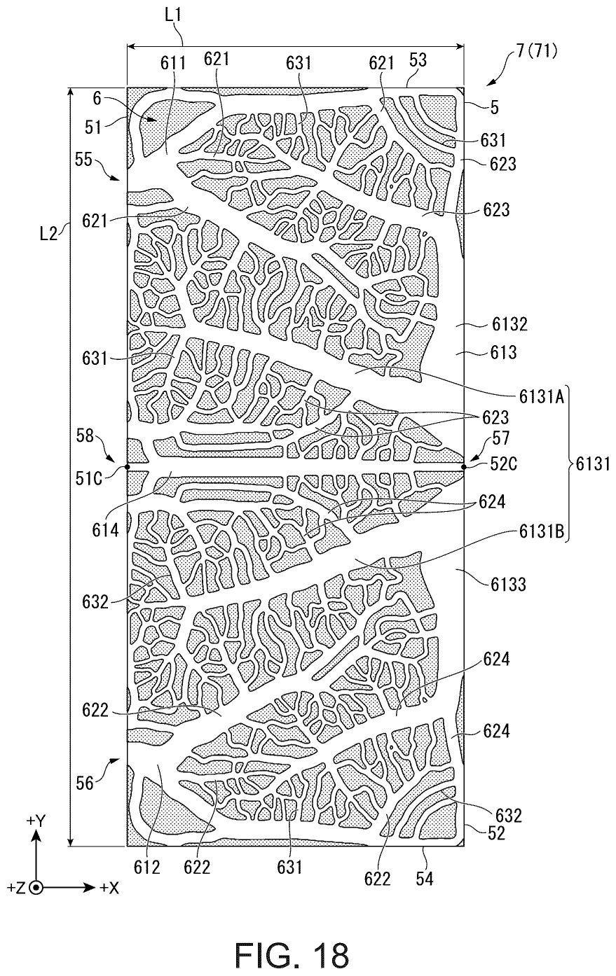

FIG. 18 is a cross-sectional view showing the internal configuration of the heat exchanger 7 included in the cooling device of the projector according to the present embodiment. Specifically, FIG. 18 is a cross-sectional view showing an internal configuration of a heat exchanger 71 of the heat exchangers 7, wherein the heat exchanger 71 includes the first flow port 55 provided at a position separated from a center 51C of the first side surface 51 toward the third side surface 53 by a length of 0.75 assuming that a length from the center 51C of the first side surface 51 to the third side surface 53 is 1, the second flow port 56 provided at a position separated from the center 51C of the first side surface 51 toward a fourth side surface 54 by a length of 0.75 assuming that a length from the center 51C of the first side surface 51 to the fourth side surface 54 is 1, a third flow port 57, and a fourth flow port 58 provided at the center 51C of the first side surface 51, and an aspect ratio of a accommodation chamber 6 of the heat exchanger 71 is 2.25. In FIG. 18, only some first branch flow paths 621 of the plurality of first branch flow paths 621 are denoted by reference numerals. The same applies to the second branch flow paths 622, the third branch flow paths 623, the fourth branch flow paths 624, the first narrow branch flow paths 631, and the second narrow branch flow paths 632. The projector according to the present embodiment has substantially the same configuration and function as those of the projector 1 according to the first embodiment except that the heat exchanger 7, an example of which is shown in FIG. 18, is provided instead of the heat exchanger 4. That is, the cooling device according to the present embodiment has the same configuration and function as the cooling device 3 according to the first embodiment except that the heat exchanger 7 is provided instead of the heat exchanger 4. That is, the cooling device according to the present embodiment includes a plurality of heat exchangers 7. Although not shown, the plurality of heat exchangers 7 include a red heat exchanger connected to the heat receiving plate 22R in a heat transferable manner, a green heat exchanger connected to the heat receiving plate 22G in a heat transferable manner, and a blue heat exchanger connected to the heat receiving plate 22B in a heat transferable manner.

### Configuration of Heat Exchanger

Similar to the heat exchanger 4, the heat exchanger 7 is a cold plate that transfers heat received from a heat-generating element to refrigerant flowing inside to cool the heat-generating element. The heat exchanger 7 has the same configuration and function as the heat exchanger 4 according to the first embodiment except that the heat exchanger 7 further includes a fourth flow port 58 and a fourth main flow path 614. That is, the heat exchanger 7 includes the housing 5 having the accommodation chamber 6 surrounded by the first side surface 51, the second side surface 52, the third side surface 53, and the fourth side surface 54, the first flow port 55, the second flow port 56, the third flow port 57, the fourth flow port 58, the first main flow path 611, the second main flow path 612, the third main flow path 613, the fourth main flow path 614, the branch flow path 621, 622, 623, 624 and the narrow branch flow path 631, 632.

Note that although not shown, in the heat exchanger 7, when the dimension ratio L2/L1 is 4.0 or more, the first main flow path 611 extends from the first flow port 55 toward the fourth side surface 54 along the first side surface 51, and also extends toward the second side surface 52 along the third side surface 53. In the heat exchanger 7, when the dimension ratio L2/L1 is 4.0 or more, the second main flow path 612 extends from the second flow port 56 toward the third side surface 53 along the first side surface 51, and also extends toward the second side surface 52 along the fourth side surface 54.

The fourth flow port 58 is disposed between the first flow port 55 and the second flow port 56 on the first side surface 51 of the housing 5. To be specific, the fourth flow port 58 is disposed at the center 51C of the first side surface 51. The fourth flow port 58 allows the outside of the housing 5 and the inside of the accommodation chamber 6 to communicate with each other. The refrigerant circulating through the cooling device can flow through the fourth flow port 58. The fourth main flow path 614 communicates with the outside of the housing 5 via the fourth flow port 58. The fourth main flow path 614 extends from the fourth flow port 58 toward the second side surface 52 in the accommodation chamber 6, and communicates with each of the third branch flow path 623 and the fourth branch flow path 624. In the heat exchanger 71, which is an example of the heat exchanger shown in FIG. 18, the flow path cross-sectional area of the fourth main flow path 614 is smaller than the flow path cross-sectional area of the third main flow path 613 on the third flow port 57 side.

Note that in the heat exchanger 71, the third main flow path 613 is constituted by the first partial flow path 6131, the second partial flow path 6132, and the third partial flow path 6133. The first partial flow path 6131 communicates with the outside of the housing 5 via the third flow port 57. The first partial flow path 6131 includes first partial flow paths 6131A and 6131B sandwiching the fourth main flow path 614 in the Y-axis. The first partial flow path 6131A extends between the first main flow path 611 and the fourth main flow path 614, and the first partial flow path 6131B extends between the second main flow path 612 and the fourth main flow path 614. Note that the flow path cross-sectional area of each of the partial flow paths 6131A and 6131B decreases as the distance from the third flow port 57 increases. The second partial flow path 6132 is a flow path that extends from the first partial flow path 6131A along the second side surface 52 toward the third side surface 53 and through which the refrigerant can flow. The flow path cross-sectional a of the second partial flow path 6132 decreases toward the first side surface 51. The third partial flow path 6133 is a flow path that extends from the first partial flow path 6131B along the second side surface 52 toward the fourth side surface 54 and through which the refrigerant can flow. The flow path cross-sectional area of the third partial flow path 6133 decreases toward the first side surface 51.

### Flow Path of Refrigerant in Accommodation Chamber

In the heat exchanger 71, when the flow ports 55, 56, and 58 are used as an inlet port of the refrigerant and the flow port 57 is used as an outlet port of the refrigerant, the refrigerant flows through the first main flow path 611, the second main flow path 612, and the fourth main flow path 614. The refrigerant flowing through the first main flow path 611 flows through the first partial flow path 6131A or the second partial flow path 6132 of the third main flow path 613 via at least one of the first branch flow path 621, the first narrow branch flow path 631, and the third branch flow path 623. The refrigerant flowing through the second main flow path 612 flows through the first partial flow path 6131B or the third partial flow path 6133 of the third main flow path 613 via at least one of the second branch flow path 622, the second narrow branch flow path 632, and the fourth branch flow path 624. The refrigerant flowing through the fourth main flow path 614 flows to the first partial flow path 6131A via the third branch flow path 623 and the first narrow branch flow path 631, and flows to the first partial flow path 6131B via the fourth branch flow path 624 and the second narrow branch flow path 632. As described above, the refrigerant flows through the plurality of branch flow paths and the plurality of narrow branch flow paths formed in the accommodation chamber 6, so that the heat transferred to the heat exchanger 7 including the heat exchanger 71 can be easily transferred to the refrigerant. Note that when the flow port 57 is used as an inlet port of the refrigerant and the flow ports 55, 56, and 58 are used as outlet ports of the refrigerant, the refrigerant flows in a direction opposite to the above.

### Efficiency of Heat Transfer of Heat Exchanger

As in the heat exchanger 4 according to the first embodiment, the heat exchanger can be configured such that the distances from the center 51C of the first side surface 51 to the first flow port 55 and the second flow port 56 are different. For example, the heat exchanger 71 shown in FIG. 18 is a heat exchanger 71 that includes the first flow port 55 provided at a position separated from the center 51C of the first side surface 51 toward the third side surface 53 by a length of 0.75, assuming that the length from the center 51C of the first side surface 51 to the third side surface 53 is 1, the second flow port 56 provided at a position separated from the center 51C of the first side surface 51 toward the fourth side surface 54 by a length of 0.75, assuming that the length from the center 51C of the first side surface 51 to the fourth side surface 54 is 1, and the fourth flow port 58 provided at the center 51C of the first side surface 51.

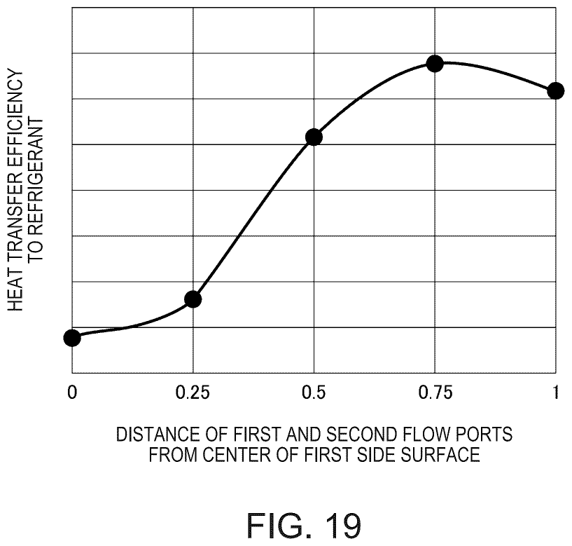

FIG. 19 is a graph showing the efficiency of heat transfer to the refrigerant by the heat exchanger 7 having the flow port 55, 56 at different positions. In the heat exchanger 7 having the flow ports 55 to 58, the efficiency of heat transfer to the refrigerant also changes depending on the positions of the first flow port 55 and the second flow port 56 in the first side surface 51. The inventor of the present disclosure investigated the efficiencies of heat transfer to the refrigerant using the heat exchanger 7 in which the distances from the center 51C of the first side surface 51 to the first flow port 55 and the second flow port 56 were different from each other, similarly to the heat exchangers 41 to 45 described above. As a result, as shown in FIG. 19, in the heat exchanger 7, it was found that in a heat exchanger 7 in which the first flow port 55 and the second flow port 56 are disposed at a position separated by a length of 0.5 or more and 1 or less from the center 51C of the first side surface 51, the efficiency of heat transfer to the refrigerant is relatively high, whereas in a heat exchanger 7 in which the first flow port 55 and the second flow port 56 are disposed at a position separated by a length of 0 or more and less than 0.5 from the center 51C of the first side surface 51, the efficiency of heat transfer to the refrigerant is relatively low. It was also found that the efficiency of heat transfer to the refrigerant by the heat exchanger 7 in which the flow ports 55, 56 are disposed at a position separated by a length of 0.75 to 1 from the center 51C of the first side surface 51 is even higher than the efficiency of heat transfer to the refrigerant by the other heat exchangers 7, and that the efficiency of heat transfer to the refrigerant by the heat exchanger 71 in which the flow ports 55, 56 are disposed at a position separated by a length of 0.75 from the center 51C of the first side surface 51 is the highest.

From the above, it is desirable that the cooling device according to the present embodiment includes a heat exchanger 7 having the first flow port 55 disposed at a position separated from the center 51C of the first side surface 51 toward the third side surface 53 by a length of 0.5 or more and 1 or less, assuming that the length from the center 51C of the first side surface 51 to the third side surface 53 is 1, and the second flow port 56 disposed at a position separated from the center 51C of the first side surface 51 toward the fourth side surface 54 by a length of 0.5 or more and 1 or less, assuming that the length from the center 51C of the first side surface 51 to the fourth side surface 54 is 1. Further, the cooling device according to the present embodiment desirably employs the heat exchanger 7 having the first flow port 55 disposed at a position that is a length of 0.75 or more and 1 or less separated from the center 51C of the first side surface 51 toward the third side surface 53, and the second flow port 56 disposed at a position that is a length of 0.75 or more and 1 or less separated from the center 51C of the first side surface 51 toward the fourth side surface 54.

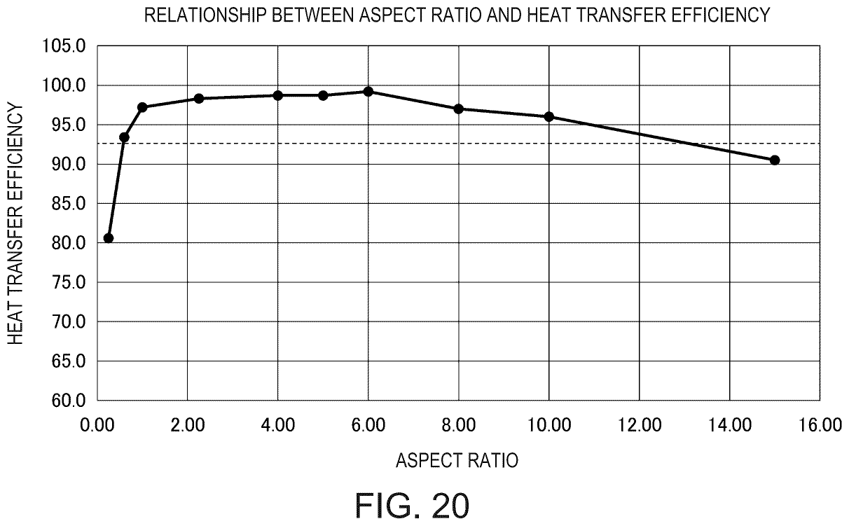

FIG. 20 is a graph showing efficiencies of heat transfer to the refrigerant by the heat exchanger 7 having different dimension ratios L2/L1. Note that in the graph shown in FIG. 20, the efficiency of heat transfer of the heat exchanger 4A4, which has the highest efficiency of heat transfer among the heat exchangers 4A in the first embodiment described above, is set to 100%, and the efficiency of heat transfer to the refrigerant by each heat exchanger 7 is shown. In the heat exchangers 7 having the flow ports 55 to 58, the efficiency of heat transfer to the refrigerant changes depending on the aspect ratio, which is the dimension ratio L2/L1. The inventor of the present disclosure investigated the efficiency of heat transfer to the refrigerant using heat exchangers 7 having different dimension ratios L2/L1 of the length L2 of the accommodation chamber 6 along the first side surface 51 to the length L1 of the accommodation chamber 6 along the third side surface 53, similar to the heat exchangers 4A1 to 4A10 described above. As a result, as shown in FIG. 20, it was found that, of the heat exchangers 7, the efficiency of heat transfer to the refrigerant by the heat exchanger 7 having the dimension ratio L2/L1 of 0.6 or more and 10.0 or less is higher than the efficiency of heat transfer to the refrigerant by the heat exchanger 7 having the dimension ratio L2/L1 of less than 0.6 and the efficiency of heat transfer to the refrigerant by the heat exchanger 7 having the dimension ratio L2/L1 of more than 10.0. It was also found that the heat exchangers 7 with a dimension ratio L2/L1 of 1.0 or more and 10.0 or less had higher efficiency of heat transfer to the refrigerant than the efficiency of heat transfer to the refrigerant of the other heat exchangers 7, and that the heat exchangers 7 having a dimension ratio L2/L1 of 1.0 or more and 4.0 or less had higher efficiency of heat transfer to the refrigerant than the efficiency of heat transfer to the refrigerant of the other heat exchangers 7. Therefore, the cooling device according to the present embodiment desirably employs a heat exchanger 7 having a dimension ratio L2/L1 of 0.6 or more and 10.0 or less, more desirably employs a heat exchanger 7 having a dimension ratio L2/L1 of 1.0 or more and 10.0 or less, and even more desirably employs a heat exchanger 7 having a dimension ratio L2/L1 of 1.0 or more and 4.0 or less.

### Effects of Second Embodiment

The projector in the present embodiment has the following additional effects, similar to those of the projector 1 in the first embodiment. The heat exchanger 7 in which the dimension ratio L2/L1 is 0.6 or more and 10.0 or less includes a fourth flow port 58 and a fourth main flow path 614 in addition to the configuration of the heat exchangers 4A2 to 4A9. The fourth flow port 58 is disposed at the center 51C of the first side surface 51 and allows the outside of the housing 5 and the inside of the accommodation chamber 6 to communicate with each other. The refrigerant can flow through the fourth flow port 58. The fourth main flow path 614 extends from the fourth flow port 58 toward the second side surface 52, and communicates with each of the third branch flow path 623 and the fourth branch flow path 624. In the present embodiment, the flow path cross-sectional area of the fourth main flow path 614 is smaller than the flow path cross-sectional area of the third main flow path 613 on the third flow port 57 side. According to such a configuration, the flow rate of the refrigerant flowing through the heat exchanger 7 can be increased. Therefore, the efficiency of heat transfer to the refrigerant by the heat exchanger 7 can be enhanced. Note that since the flow path cross-sectional area of the fourth main flow path 614 extending from the fourth flow port 58 is smaller than the flow path cross-sectional area of the third main flow path 613, the surface area of the flow path can be increased over the entire accommodation chamber 6, and thus the contact area with the refrigerant in the accommodation chamber 6 can be enlarged.

In the heat exchanger 7 in which the dimension ratio L2/L1 is 0.6 or more and 10.0 or less, the third main flow path 613 includes the first partial flow path 6131, the second partial flow path 6132, and the third partial flow path 6133.

The first partial flow path 6131 communicates with the outside of the housing 5 via the third flow port 57. The second partial flow path 6132 extends from the first partial flow path 6131 toward the third side surface 53. The third partial flow path 6133 extends from the first partial flow path 6131 toward the fourth side surface 54.

According to such a configuration, refrigerant can be caused to flow between the first main flow path 611 and the fourth main flow path 614 and the third main flow path 613, and also the refrigerant can be caused to flow between the second main flow path 612 and the fourth main flow path 614 and the third main flow path 613. Therefore, when one of the first flow port 55, the second flow port 56, the fourth flow port 58, and the third flow port 57 is an inlet port through which the refrigerant flows into the accommodation chamber 6, and the other is an outlet port for discharging the refrigerant that has flowed through the accommodation chamber 6, the refrigerant can easily flow through the accommodation chamber 6. Therefore, the efficiency of heat transfer to the refrigerant by the heat exchanger 7 can be enhanced.

### Modifications of the Embodiment

The present disclosure is not limited to the above-described embodiments, and modifications, improvements, and the like within a range in which the object of the present disclosure can be achieved are included in the present disclosure. In the first embodiment, for example, the heat exchangers 4A2 to 4A9 in which the dimension ratio L2/L1 is 0.6 or more and 10.0 or less, have a first flow port 55 and a second flow port 56 provided on the first side surface 51, and one third flow port 57 provided on the second side surface 52. In the second embodiment, the heat exchanger 7 in which the dimension ratio L2/L1 is 0.6 or more and 10.0 or less, has a first flow port 55, a second flow port 56, and a fourth flow port 58 provided on the first side surface 51, and a third flow port 57 provided on the second side surface 52. However, the present disclosure is not limited to these, and the number of the flow ports provided in the first side surface 51 may be four or more, and the number of the flow ports provided in the second side surface 52 may be two or more.

In each of the above-described embodiments, the accommodation chamber 6 is formed in a rectangular shape surrounded by the side surfaces 51 to 54 when viewed from the ±Z direction. However, the present disclosure is not limited to this, and the accommodation chamber 6 may have another polygonal shape when viewed from the ±Z direction, or may be formed in a circular shape including an ellipse.

In each of the embodiments described above, the accommodation chamber 6 is configured to be line-symmetric with respect to the imaginary straight line passing through the center 51C of the first side surface 51 and orthogonal to the first side surface 51. However, the present disclosure is not limited to this, and in the accommodation chamber 6, the arrangement of each flow path 611 to 614, 621 to 624, 631, 632, the area on the third side surface 53 side of the imaginary straight line and the area on the fourth side surface 54 side of the imaginary straight line do not have to be line-symmetric about the imaginary straight line.

In each of the embodiments described above, the third flow port 57 is disposed at the center 52C of the second side surface 52 in the Y-axis direction. However, the present disclosure is not limited to this, and the third flow port 57 may be shifted from the center 52C to the third side surface 53 side or the fourth side surface 54 side in the second side surface 52. Furthermore, the third main flow path 613 connected to the third flow port 57 may be disposed to be biased toward the third side surface 53 or the fourth side surface 54.

In the above-described embodiments, the heat exchangers 4A2 to 4A9, 7 in which the dimension ratio L2/L1 is, for example, 0.6 or more and 10.0 or less, include the first narrow branch flow path 631 and the second narrow branch flow path 632. However, the present disclosure is not limited to this, and at least one of the first narrow branch flow path 631 and the second narrow branch flow path 632 may be omitted. The plurality of first narrow branch flow paths 631 include the flow path that allows the first branch flow path 621 and the third branch flow path 623 to communicate with each other. However, the present disclosure is not limited to this, and each of the plurality of first narrow branch flow paths 631 provided in the first branch flow path 621 may be connected to the third main flow path 613, and each of the plurality of first narrow branch flow path 631 provided in the third branch flow path 623 may be connected to the first main flow path 611. The same applies to the second narrow branch flow paths 632.

In the first embodiment, the first target side surface along which the first main flow path 611 extends is determined according to the comparison result between the half of the length of the first side surface 51 along the Y axis and the length of the third side surface 53 along the X axis, and the second target side surface along which the second main flow path 612 extends is determined according to the comparison result between the half of the length of the first side surface 51 along the Y axis and the length of the fourth side surface 54 along the X axis. However, the present disclosure is not limited thereto, and the extending direction of each of the first main flow path 611 and the second main flow path 612 may be determined based on a predetermined mathematical expression.

In each of the above-described embodiments, the cooling device 3 includes the heat exchangers 4A2 to 4A9, 7, the storage container 31, the radiator 32, the pump 33, and the pipe 34, each of which has the dimension ratio L2/L1 of 0.6 or more and 10.0 or less. However, the present disclosure is not limited to this, and the storage container 31 may be omitted, and the configuration of the cooling device of the present disclosure is not limited to the above. In addition, in each of the above embodiments, the refrigerant flowing through the heat exchangers 4A2 to 4A9, 7 in which the dimension ratio L2/L1 is 0.6 or more and 10.0 or less is a liquid refrigerant, but the present disclosure is not limited to this, and it may be a gaseous refrigerant.

In the above first embodiment, the cooling device 3 includes the red heat exchanger 4R, green heat exchanger 4G, and blue heat exchanger 4B. However, the number of heat exchangers included in the cooling device 3 is not limited to this, and can be changed as appropriate. The same applies to the cooling device according to the second embodiment. In the first embodiment, the refrigerant sent out from the pump 33 flows through the blue heat exchanger 4B, the green heat exchanger 4G, and the red heat exchanger 4R in this order. However, the order of flow of the refrigerant in the plurality of heat exchangers is not limited to this, and can be changed as appropriate. The refrigerant sent out from the pump 33 may be divided by the pipe 34 and flow in parallel through the blue heat exchanger 4B, the green heat exchanger 4G, and the red heat exchanger 4R. The same applies to the cooling device according to the second embodiment.

In each of the above embodiments, the heat exchangers 4A2 to 4A9, 7, in which the dimension ratio L2/L1 is 0.6 or more and 10.0 or less, are connected in a manner capable of transferring heat to the heat receiving plate 22 connected to the light source 21, which is a heat-generating element. That is, the heat exchangers according to the above embodiments are configured to cool the light source 21, which is a heat-generating element. However, the present disclosure is not limited to this, and the heat receiving plate 22 may be connected to another heat-generating element, and the heat exchanger may cool another heat-generating element. For example, the heat receiving plate 22 may be provided in the light modulation element 23, and the heat exchanger may be connected to the heat receiving plate 22 provided in the light modulation element 23 in a heat transferable manner. Further, the heat receiving plate 22 may be omitted depending on the configuration of the heat-generating elements to be cooled.

In each of the above embodiments, the projector 1 includes the three light modulation elements 23R, 23G, and 23B. However, the present disclosure is not limited to this, and can also be applied to a projector including two or less light modulation elements or four or more light modulation elements.

In each of the above embodiments, the light modulation element 23 includes a transmissive liquid crystal panel having a light incident surface and a light exiting surface different from each other. However, the present disclosure is not limited to this, and the light modulation element may include a reflective liquid crystal panel in which the light incident surface and the light emission surface are the same. Further, it is also possible to adopt a light modulation element other than the liquid crystal, such as a device using a micromirror, for example, a device using a DMD (Digital Micromirror Device), as long as the light modulation device is capable of modulating the incident luminous flux to form an image corresponding to the image information.

In each of the above embodiments, the light sources 21 include the red light source 21R, the green light source 21G, and the blue light source 21B, and the light sources 21R, 21G, and 21B each include the light emitting elements. However, the present disclosure is not limited to this, and the light source 21 may be configured from a light emitting element and a wavelength conversion element that converts the wavelength of light emitted from the light emitting element, or may be configured from a discharge light source lamp such as an ultra-high pressure mercury lamp. That is, the configuration of the light source is not limited.

In each of the above embodiments, the example has been given in which the cooling device 3 including the heat exchangers 4A2 to 4A9, 7 is applied to the projector. However, the present disclosure is not limited to this, and the cooling device including the heat exchangers 4A2 to 4A9 and 7 may be applied to an electronic device other than a projector. For example, the heat exchanger of the present disclosure may be used for cooling an integrated circuit included in an electronic device. Further, the heat exchangers 4A2 to 4A9 and the heat exchanger 7 in which the first flow port 55 and the second flow port 56 are disposed at a position separated from the center 51C of the first side surface 51 by a length of 0.5 to 1 and the dimension ratio L2/L1 is 0.6 to 10.0 may be used in devices other than cooling devices.

### SUMMARY OF THE PRESENT DISCLOSURE

Hereinafter, a summary of the present disclosure is appended.

### Appendix 1

A heat exchanger includes
a housing having a first side surface and a second side surface located on opposite sides, a third side surface and a fourth side surface that intersect both the first side surface and the second side surface, and that are located on opposite sides, and an accommodation chamber surrounded by the first side surface, the second side surface, the third side surface, and the fourth side surface;
a first flow port disposed in the first side surface in a range from a half of a length to the third side surface from a center of the first side surface to the third side surface, and through which a refrigerant can flow;
a second flow port disposed in the first side surface in a range from a half of a length to the fourth side surface from a center of the first side surface to the fourth side surface, and through which the refrigerant can flow;
a third flow port that is disposed in the second side surface and through which the refrigerant can flow;
a first main flow path that communicates with the outside of the housing via the first flow port and that extends in the accommodation chamber along a first target side surface that is one side surface of the first side surface and the third side surface;
a second main flow path that communicates with the outside of the housing via the second flow port and that extends in the accommodation chamber along a second target side surface that is one side surface of the first side surface and the fourth side surface;
a third main flow path that communicates with the outside of the housing via the third flow port and that extends in the accommodation chamber along one main flow path of the first main flow path and the second main flow path;
a plurality of first branch flow paths that are provided at a plurality of locations in the first main flow path and that branch off from the first main flow path;
a plurality of second branch flow paths that are provided at a plurality of locations in the second main flow path and that branch off from the second main flow path;
a plurality of third branch flow paths that are provided in a portion of the third main flow path on the first main flow path side and that communicate with at least one first branch flow path of the plurality of first branch flow paths; and
a plurality of fourth branch flow paths that are provided in a portion of the third main flow path on the second main flow path side and that communicate with at least one second branch flow path of the plurality of second branch flow paths, wherein
a dimension ratio of a length of the accommodation chamber along the first side surface to a length of the accommodation chamber along the third side surface is 0.6 or more and 10.0 or less.

According to such a configuration, the first flow port is disposed in the range from the half of the length from the center of the first side surface to the third side surface to the third side surface on the first side surface, and the second flow port is disposed in the range from the half of the length from the center of the first side surface to the fourth side surface to the fourth side surface on the first side surface. According to this configuration, as shown by the result of testing by the inventor of present disclosure, the efficiency of heat transfer to the refrigerant by the heat exchanger can be enhanced. In the heat exchanger, the dimension ratio of the length of the accommodation chamber along the first side surface to the length of the accommodation chamber along the third side surface is 0.6 or more and 10.0 or less, and thus the efficiency of heat transfer of the heat exchanger to the refrigerant can be increased as compared to when the dimension ratio is less than 0.6 and exceeds 10.0. Therefore, a heat exchanger having a high efficiency of heat transfer to the refrigerant can be configured.

### Appendix 2

The heat exchanger according to Appendix 1, wherein
the dimension ratio of the length of the accommodation chamber along the first side surface to the length of the accommodation chamber along the third side surface is 1.0 or more and 4.0 or less.

According to such a configuration, the refrigerant can be easily flow efficiently in the entire accommodation chamber, and the pressure loss of the refrigerant can be further reduced. Therefore, the efficiency of heat transfer to the refrigerant by the heat exchanger can be further enhanced.

### Appendix 3

The heat exchanger according to Appendix 1 or Appendix 2, wherein
the accommodation chamber is formed in a rectangular shape when viewed from a third direction orthogonal to both of a first direction orthogonal to the first side surface and a second direction orthogonal to the third side surface.

According to such a configuration, it is possible to easily cause the refrigerant from one flow port to the other flow port among the first flow port and the second flow port, and the third flow port while enabling the refrigerant to spread throughout the entire accommodation chamber. Therefore, the efficiency of heat transfer to the refrigerant by the heat exchanger can be further enhanced.

### Appendix 4

The heat exchanger according to Appendix 3 wherein
the accommodation chamber is configured to be line-symmetrical about an imaginary straight line passing through a center of the first side surface and orthogonal to the first side surface.

According to such a configuration, the design of the accommodation chamber in which the flow paths are provided, and thus the design of the heat exchanger, can be simplified.

### Appendix 5

The heat exchanger according to any one of Appendix 1 to Appendix 4, wherein
a flow path cross-sectional area of the first branch flow path is smaller than a flow path cross-sectional area of the first main flow path,
a flow path cross-sectional area of the second branch flow path is smaller than a flow path cross-sectional area of the second main flow path, and
each of a flow path cross-sectional area of the third branch flow path and a flow path cross-sectional area of the fourth branch flow path is smaller than the flow path cross-sectional area of the third main flow path.

According to such a configuration, a larger number of first branch flow paths can be provided in the first main flow path, and a larger number of second branch flow paths can be provided in the second main flow path. Similarly, more third branch flow paths may be provided in the third main flow path, and more fourth branch flow paths may be provided in the third main flow path. Therefore, the contact area with the refrigerant in the accommodation chamber can be increased, and thus the efficiency of heat transfer to the refrigerant by the heat exchanger can be enhanced.

### Appendix 6

The heat exchanger according to Appendix 5 further including
a plurality of first narrow branch flow paths each having a flow path cross-sectional area smaller than each of the flow path cross-sectional area of the first branch flow path and the flow path cross-sectional area of the third branch flow path and
a plurality of second narrow branch flow paths each having a flow path cross-sectional area smaller than each of the flow path cross-sectional area of the second branch flow path and the flow path cross-sectional area of the fourth branch flow path, wherein
the plurality of first narrow branch flow paths include a flow path that allows the first branch flow path and the third branch flow path to communicate with each other and
the plurality of second narrow branch flow paths include a flow path that allows the second branch flow path and the fourth branch flow path to communicate with each other.

According to such a configuration, the surface area of the flow path can be increased over the entire accommodation chamber, and thus, the contact area with the refrigerant in the accommodation chamber can be enlarged, and an increase in pressure loss can be suppressed. According to this configuration, the efficiency of heat transfer to the refrigerant by the heat exchanger can be enhanced.

### Appendix 7

The heat exchanger according to any one of Appendix 1 to Appendix 6, wherein
the first target side surface is
   the first side surface in a case where a half of the length of the first side surface is larger than the length of the third side surface,
   the third side surface in a case where a half of the length of the first side surface is smaller than the length of the third side surface, and
   at least one of the first side surface and the third side surface in a case where a half of a length of the first side surface and a length of the third side surface are equal to each other and
   the second target side surface is the first side surface in a case where half of the length of the first side surface is larger than the length of the fourth side surface,
   the fourth side surface in a case where half of the length of the first side surface is smaller than the length of the fourth side surface, and
   when half of the length of the first side surface is equal to the length of the fourth side surface, the side surface is at least one of the first side surface and the fourth side surface.

According to such a configuration, the first main flow path can be extended linearly and elongated in the accommodation chamber, and the second main flow path can be extended linearly and elongated in the accommodation chamber. Accordingly, the flow path resistance of the first main flow path and the flow path resistance of the second main flow path can be reduced, and thus, an increase in the pressure loss of the refrigerant can be suppressed. Therefore, the efficiency of heat transfer to the refrigerant by the heat exchanger can be enhanced.

### Appendix 8

The heat exchanger according to any one of Appendix 1 to Appendix 6, further including
a fourth flow port disposed at a center of the first side surface and through which a refrigerant can flow and
a fourth main flow path that communicates with the outside of the housing via the fourth flow port, that extends toward the second side surface in the accommodation chamber, and that communicates with each of the third branch flow path and the fourth branch flow path.

According to such a configuration, the flow rate of the refrigerant flowing through the heat exchanger can be increased. In addition, the surface area of the flow path can be increased over the entire accommodation chamber, and thus the contact area with the refrigerant in the accommodation chamber can be enlarged. Therefore, the efficiency of heat transfer to the refrigerant by the heat exchanger can be enhanced.

### Appendix 9

The heat exchanger according to Appendix 8, wherein
the third main flow path includes
   a first partial flow path communicating with the outside of the housing via the third flow port,
   a second partial flow path extending from the first partial flow path toward the third side surface; and
   a third partial flow path extending from the first partial flow path toward the fourth side surface.

According to such a configuration, the refrigerant can be caused to flow between the first main flow path and the fourth main flow path and the third main flow path, and also a refrigerant can be cause to flow between the second main flow path and the fourth main flow path and the third main flow path. Therefore, when one of the first flow port, the second flow port, the fourth flow port, and the third flow port is an inlet port through which the refrigerant flows into the accommodation chamber, and the other is an outlet port for discharging the refrigerant that has flowed through the accommodation chamber, the refrigerant can easily flow through the accommodation chamber. Therefore, the efficiency of heat transfer to the refrigerant by the heat exchanger can be enhanced.

### Appendix 10

The heat exchanger according to any one of Appendix 1 to Appendix 9, wherein
assuming that a length from the center of the first side surface to the third side surface is 1, the first flow port is disposed separated from the center of the first side surface toward the third side surface by a length of 0.75 or more and 1 or less and
assuming that a length from the center of the first side surface to the fourth side surface is 1, the second flow port is disposed separated from the center of the first side surface toward the fourth side surface by a length of 0.75 or more and 1 or less.

According to such a configuration, since each of the first main flow path and the second main flow path can be extended substantially linearly, the flow path resistance of each main flow path can be reduced, and the contact area with the refrigerant in the accommodation chamber can be further enlarged. Therefore, the efficiency of heat transfer to the refrigerant by the heat exchanger can be further enhanced.

### Appendix 11

A cooling device includes
the heat exchanger according to any one of Appendix 1 to Appendix 10;
a radiator that radiates heat received by the refrigerant in the heat exchanger; and
a pump that circulates the refrigerant between the heat exchanger and the radiator.

According to such a configuration, the same effect as that of the heat exchanger described above can be achieved, and a cooling device having high cooling efficiency of the cooling target can be configured.

### Appendix 12

A projector includes
the cooling device according to Appendix 11;
a light source;
a light modulation element that modulates light emitted from the light source;
a projection optical device that projects the modulated light; and
a heat receiving plate provided on a heat-generating element of one of the light source and the light modulation element, wherein
the heat exchanger of the cooling device is connected to the heat receiving plate in a heat transferable manner.

According to such a configuration, it is possible to increase the cooling efficiency of the heat-generating element of one of the light source and the image forming panel. Thus, even when the amount of light incident on the light modulation element from the light source is increased, the temperature rise of the heat-generating element can be suppressed, and therefore, a projector capable of projecting high-luminance image light can be configured.

### Appendix 13

An electronic device includes
the cooling device according to Appendix 11 and
a heat-generating element having a heat receiving plate, wherein
the heat exchanger of the cooling device is connected to the heat receiving plate in a heat transferable manner.

According to such a configuration, the cooling efficiency of the heat-generating element can be enhanced, and thus an electronic device capable of operating stably can be configured.

What is claimed is:

1. A heat exchanger comprising:
a housing having a first side surface and a second side surface located on opposite sides, a third side surface and a fourth side surface that intersect both the first side surface and the second side surface, and that are located on opposite sides, and an accommodation chamber surrounded by the first side surface, the second side surface, the third side surface, and the fourth side surface;
a first flow port disposed in the first side surface in a range from a half of a length to the third side surface from a center of the first side surface to the third side surface, and through which a refrigerant can flow;
a second flow port disposed in the first side surface in a range from a half of a length to the fourth side surface from a center of the first side surface to the fourth side surface, and through which the refrigerant can flow;
a third flow port that is disposed in the second side surface and through which the refrigerant can flow;
a first main flow path that communicates with the outside of the housing via the first flow port and that extends in the accommodation chamber along a first target side surface that is one side surface of the first side surface and the third side surface;
a second main flow path that communicates with the outside of the housing via the second flow port and that extends in the accommodation chamber along a second target side surface that is one side surface of the first side surface and the fourth side surface;
a third main flow path that communicates with the outside of the housing via the third flow port and that extends in the accommodation chamber along one main flow path of the first main flow path and the second main flow path;
a plurality of first branch flow paths that are provided at a plurality of locations in the first main flow path and that branch off from the first main flow path;
a plurality of second branch flow paths that are provided at a plurality of locations in the second main flow path and that branch off from the second main flow path;
a plurality of third branch flow paths that are provided in a portion of the third main flow path on the first main flow path side and that communicate with at least one first branch flow path of the plurality of first branch flow paths; and
a plurality of fourth branch flow paths that are provided in a portion of the third main flow path on the second main flow path side and that communicate with at least one second branch flow path of the plurality of second branch flow paths, wherein
a dimension ratio of a length of the accommodation chamber along the first side surface to a length of the accommodation chamber along the third side surface is 0.6 or more and 10.0 or less.

2. The heat exchanger according to claim 1, wherein
the dimension ratio of the length of the accommodation chamber along the first side surface to the length of the accommodation chamber along the third side surface is 1.0 or more and 4.0 or less.

3. The heat exchanger according to claim 1, wherein
the accommodation chamber is formed in a rectangular shape when viewed from a third direction orthogonal to both of a first direction orthogonal to the first side surface and a second direction orthogonal to the third side surface.

4. The heat exchanger according to claim 3, wherein
the accommodation chamber is configured to be line-symmetrical about an imaginary straight line passing through a center of the first side surface and orthogonal to the first side surface.

5. The heat exchanger according to claim 1, wherein
a flow path cross-sectional area of the first branch flow path is smaller than a flow path cross-sectional area of the first main flow path,
a flow path cross-sectional area of the second branch flow path is smaller than a flow path cross-sectional area of the second main flow path, and
each of a flow path cross-sectional area of the third branch flow path and a flow path cross-sectional area of the fourth branch flow path is smaller than the flow path cross-sectional area of the third main flow path.

6. The heat exchanger according to claim 5, further comprising:
a plurality of first narrow branch flow paths each having a flow path cross-sectional area smaller than each of the flow path cross-sectional area of the first branch flow path and the flow path cross-sectional area of the third branch flow path and
a plurality of second narrow branch flow paths each having a flow path cross-sectional area smaller than each of the flow path cross-sectional area of the second branch flow path and the flow path cross-sectional area of the fourth branch flow path, wherein
the plurality of first narrow branch flow paths include a flow path that allows the first branch flow path and the third branch flow path to communicate with each other and
the plurality of second narrow branch flow paths include a flow path that allows the second branch flow path and the fourth branch flow path to communicate with each other.

7. The heat exchanger according to claim 1, wherein
the first target side surface is
the first side surface in a case where a half of the length of the first side surface is larger than the length of the third side surface,
the third side surface in a case where a half of the length of the first side surface is smaller than the length of the third side surface, and
at least one of the first side surface and the third side surface in a case where a half of a length of the first side surface and a length of the third side surface are equal to each other and
the second target side surface is
the first side surface in a case where half of the length of the first side surface is larger than the length of the fourth side surface,
the fourth side surface in a case where half of the length of the first side surface is smaller than the length of the fourth side surface, and
at least one of the first side surface and the fourth side surface in a case where half of the length of the first side surface is equal to the length of the fourth side surface.

8. The heat exchanger according to claim 1, further comprising:
a fourth flow port disposed at a center of the first side surface and through which a refrigerant can flow and
a fourth main flow path that communicates with the outside of the housing via the fourth flow port, that extends toward the second side surface in the accommodation chamber, and that communicates with each of the third branch flow path and the fourth branch flow path.

9. The heat exchanger according to claim 8, wherein
the third main flow path includes
a first partial flow path communicating with the outside of the housing via the third flow port,
a second partial flow path extending from the first partial flow path toward the third side surface, and
a third partial flow path extending from the first partial flow path toward the fourth side surface.

10. The heat exchanger according to claim 1, wherein
assuming that a length from the center of the first side surface to the third side surface is 1, the first flow port is disposed separated from the center of the first side surface toward the third side surface by a length of 0.75 or more and 1 or less and
assuming that a length from the center of the first side surface to the fourth side surface is 1, the second flow port is disposed separated from the center of the first side surface toward the fourth side surface by a length of 0.75 or more and 1 or less.

11. A cooling device comprising:
the heat exchanger according to claim 1;
a radiator that radiates heat received by the refrigerant in the heat exchanger; and
a pump that circulates the refrigerant between the heat exchanger and the radiator.

12. A projector comprising:
the cooling device according to claim 11;
a light source;
a light modulation element that modulates light emitted from the light source;
a projection optical device that projects the modulated light; and
a heat receiving plate provided on a heat-generating element of one of the light source and the light modulation element, wherein
the heat exchanger of the cooling device is connected to the heat receiving plate in a heat transferable manner.

13. An electronic device comprising:
the cooling device according to claim 11 and
a heat-generating element having a heat receiving plate, wherein
the heat exchanger of the cooling device is connected to the heat receiving plate in a heat transferable manner.
